(19) United States
(12) Patent Application Publication
(10) Pub. No.: US 2011/0289023 A1
(43) Pub. Date: Nov. 24, 2011

(54) Retail Item Display Device

(75) Inventors: Ian J. FORSTER, Essex (GB); Michael G. GINN, Essex (GB); Ming Kun SHI, Arcadi, CA (US); Sriram Venkatasanthanam, Chino Hills, CA (US)

(73) Assignee: AVERY DENNISON CORPORATION, Pasadena, CA (US)

(21) Appl. No.: 13/071,791

(22) Filed: Mar. 25, 2011

Related U.S. Application Data
(60) Provisional application No. 61/317,838, filed on Mar. 26, 2010.

(51) Int. Cl. G06K 7/01; G06Q 90/00; H05K 3/30; G06K 19/077

(52) U.S. Cl. 705/500; 235/488; 340/10.6; 29/832

(57) ABSTRACT

A retail item display includes an RFID processor, a display driving mechanism, at least one power source, and an electronic display. The RFID processor can include an antenna and an RFID processor. The display driving mechanism can include a microcontroller and a display driver or similar device. The electronic display comprises a display medium sandwiched between two electrodes. The RFID device is in communication with the display driving mechanism to display updated product information on the electronic display according to instructions from an external RFID activator. In one embodiment, the retail item display includes an electronic display that can be activated or deactivated. In another embodiment, the retail item display includes at least one customizable portion and at least one non-customizable portion. Methods to reduce the number of electrical connections between the display driving mechanism and the electronic display are also disclosed.

### CROSS-REFERENCE TO RELATED APPLICATION

The present application claims the benefit of U.S. Provisional Application No. 61/317,838 filed Mar. 26, 2010, which is incorporated herein by reference in its entirety.

### FIELD OF THE INVENTION

The present invention is in the field of item identification, merchandising and marketing and more particularly to retail item level displays that are used to provide current product and/or pricing information for consumer goods, such as apparel items, which is readily visible to prospective consumers and remotely updateable and changeable to provide new indicia such as pricing.

### BACKGROUND OF THE INVENTION

Currently, retail labeling, that is the labeling of consumer goods, such as price or identification labeling, is achieved through the use of pressure sensitive labels which are printed with information such as price or description relating to the articles to which they are connected, that may be applied directly to a consumer good or may be applied to a tag or other carrier which is then connected to the good, such as a string. The display is printed with relevant information (price, description, product codes, etc.) and then the hangtag is attached to the consumer good or otherwise associated with the article.

The conventional retail label or hangtag which has been preprinted with certain information about the associated retail product, such as a price, a SKU barcode, description or a store catalog number (e.g., a PLU code) cannot be easily changed or modified in today's retail environment. For example, if the product information displayed by the conventional hangtag or retail label needs to be updated (e.g., due to a price change), the retail label or hangtag must either be altered (e.g., by attaching another retail label), overwritten by hand or replaced with an updated retail label or hang tag which can be inefficient, costly, and time consuming. In addition, such over labeling or overwriting can make the retail label or hangtag appear sloppy and can detract from the overall appearance and hence marketing appeal of a particular product is decreased. Moreover, human errors can occur and the wrong replacement label or information is applied, potentially leading to a deeper discount than the retailer had intended when a product is initially put on sale or is set for clearance or a higher price than desired leading to consumer dissatisfaction. If the information is incorrect or misleading, a sale may not occur leaving the articles in inventory.

What is needed, is a more straightforward solution that allows the retailer to efficiently and quickly change or update a retail tag or label without the foregoing issues created by the currently available solutions.

### SUMMARY OF THE INVENTION

The embodiments of the present invention described below are not intended to be exhaustive or to limit the invention to the precise forms disclosed in the following detailed description. Rather, the embodiments are chosen and described so that others skilled in the art may appreciate and understand the principles and practices of the present invention.

In accordance with one embodiment, a retail tag is provided and includes a RFID device, a display driving mechanism, a power source, and an electronic display. The RFID device includes at least one RFID antenna and one RFID processor. The RFID device interacts with an external RFID activator to update the information related to the retail product. The RFID device also communicates with the display driving mechanism which processes the information and transfers the updated information to the display module.

The display driving mechanism includes at least one microcontroller and one display driver or other similar devices. The microcontroller (e.g. CPU, processor, etc.) and the display driver can be either separate components (e.g. standalone) or integrated or combined into a single component. The display driving mechanism may further include a storage element that is used to temporarily or permanently store the information related to the retail product.

The display driving element may also incorporate circuitry to sense the state of the display element, particularly for bistable types of display. Here the display driving element can, by sensing the state of the display element, indicate if the displayed element matched the data stored in the device, and, in the event of a discrepancy, seek to correct the mismatch and report said state in either a visual fault indicator, such as a symbol, or by clearing the display, a set state in memory which can be remotely read or both, Conditions where the display would not match the programmed data could include a mechanical or electrical fault in the tag structure or where an attempt has been made to change the display state outside of a defined set of operational parameters, such as temperature.

The display driving mechanism communicates with the RFID device, processing the information and transferring the updated pricing information or other indicia (e.g. percent off, “sale”, promotional information or the like) to the electronic display. An analog to digital signal converting element may be included to convert the RF signal from the RFID device to digital signal for processing by the display driving mechanism. The display driving mechanism may further include a charge pump to supply the voltage level necessary to activate the display module.

Alternatively, the RFID processor and the microcontroller can be integrated into a single component which collectively communicates with a standalone display driver to provide updated information related to the retail product on the electronic display.

The power source can power all or certain of the components of the retail item display to facilitate communication with an external RFID activator to update the product information. Alternatively, the power source might not power the RFID device such as when the RFID device is provided in a passive-type RFID retail tag arrangement. The power source includes a battery or an RF energy harvesting element. The harvesting element can harvest the RF energy from the surrounding environment or from the external RFID activator to power the retail label. The RF energy harvesting element can be used to charge the power source, such as a super capacitor or re-chargeable battery. Alternatively, the charging could be achieved by using an alternate energy source, such as a photovoltaic element or a device capable of recovering energy from mechanical motion. The RF energy harvesting may run at an alternate frequency to that used for the RFID communication; for example, power may be provided at a relatively low frequency, between 0.1 MHz and 20 MHz, where the RFID function is performed at a relatively high frequency, such as 860 MHz to 960 MHz. The energy may be supplied on a continuous basis, or alternatively when required, for example in the event a low battery indication it received from a tag. The charger may be in the form of a mat or covering, which is placed in proximity to the items.

The electronic display includes a display medium that is disposed between two electrodes. The upper electrode can be transparent, partially opaque, translucent, clear or have any other suitable optical properties so that the information can be observed either completely or partially through the electrode depending on its optical properties. The bottom electrode can be either transparent, translucent, partially opaque or opaque or clear, and may include a TFT or pixeled electrode to enable a high resolution display. TFT is used in a dot matrix display and pixel electrode is used in direct drive segmented display or passive display. The display medium can include any materials that change the optical appearance once power is applied across the top and bottom electrodes. Exemplary display medium includes electro-chromic medium which changes the optical appearance by chemical reaction; liquid crystal medium which changes the optical appearance by alignment of liquid crystal molecules; electrophoretic medium which changes the optical appearance by movement of charged particles; electromagnetic medium that changes the optical appearance by alignment of electromagnetic fibers and combinations thereof.

In another embodiment, the retail tag includes a secondary power source which can be used to extend the battery life and/or to ensure the normal function of the display module even if the first power source has failed. The first and second power sources can be the same, such as battery or super capacitor, or a combination of a battery and a super capacitor. However, it is advantageous to use a rechargeable battery as the first power source and a super capacitor as the second power source so that the super capacitor can charge the battery.

In one embodiment, the battery or at least one of the power sources for the retail tag is coupled with both the RFID device and the display driving mechanism to provide power to each of these devices. Such connection can extend the signal strength or the working distance of the RFID device and ensure normal functioning of the retail tag. In another embodiment, no battery or power source is connected to the RFID device, but it is connected directly to the display driving mechanism to ensure that product information remains visible in case that the primary power source or signal received from the antenna is discontinued.

In yet another embodiment, the retail tag may further include an opening to facilitate replacement of a malfunctioning power source or to change or replace the power source. While the opening can be located either on the front or backside of the retail tag, it is preferred to have the opening located on the backside of the tag to maximize the useful area of the front side of the tag.

In yet another embodiment, the retail tag may further include a compartment to house a power source. A separate power source, such as a battery, can be inserted into the compartment of the retail tag when necessary and can be removed at any time. It is preferred to have the compartment located on the backside of the tag to maximize the useful, display area of the front side of the tag, as described above.

In yet another embodiment, the retail tag further includes a power management device to provide information on the remaining power of the power source. The power management device may include a power management function built into the RFID processor or into the display driving mechanism. The information on the power level can be sent back to the central station via the external transceiver such as an RFID activator. Another power management function my include generation of a sound alarm from the retail tag when the power reaches a critical point. A further power management function includes a power indicator on the retail tag. The power indicator can be shown in the same display screen as the pricing information or in a separate display screen. When a separate display screen is used, a different display medium and driving mechanism can be used. In addition, the power level indicator may function alternately between “on” and “off” position to reduce the power consumption.

In yet another embodiment, the display module is multiplexed in order to reduce the number of electrical connections between the electronic display and the display driving mechanism. Multiplexing is particularly advantageous for the retail tag having more pricing information or numerical digits, either in the same row or in different rows.

In yet another embodiment, the display includes a plurality of alpha, numeric or a combination of alpha and numeric digits and where at least one of the alpha or numeric digits in the retail tag is kept constant and not updateable by the RFID device. The freezing of at least one digit allows the ability to reduce the number of electrical connections between the electronic display and the display driving mechanism, and consequently, the physical dimension of the chips for the display driving mechanism and the assembly costs can both be reduced.

In yet another embodiment, the retail tag having at least one customizable portion and at least one non-customizable portion. The customizable portion is configured to display an image that can be updated according to instructions from the external RFID activator and the RFID device in the tag. The non-customizable portion is configured to selectively display an image, such as a pre-printed image. The non-customizable portion may consist of information pre-recorded using the display medium on the display screen. Alternatively, the non-customizable portion may also include pre-printed information using conventional or digital printing inks on the front, the back, or both the front and the back surfaces of the display screen or tag. The information in the non-customizable portion is not updateable by the external RFID activator.

In yet another embodiment, the retail tag having at least one customizable portion and at least one partially-customizable portion. The customizable portion is configured to display an image that can be updated according to instructions from the external RFID activator and the RFID device in the tag. The partially-customizable portion is configured to display an image in the display screen. The partially-customizable portion may consist of information pre-printed using the display medium in the display screen. The information in the partially-customizable portion can be turned “on” or “off” by the external RFID activator.

In yet another embodiment, the retail tag is used in combination with a paper card to provide updated information about one or a plurality of retail products. The retail tag includes at least an RFID device, a display driving mechanism, at least one power source, and a display module. A code is displayed on the display module according to instructions from an external activator to advertise the availability of updated product information. The same code is printed on a paper card placed nearby along with updated information about one or plurality of retail products. Different codes can be used and associated with different information to be printed on the paper card. If needed, the information on the paper card can be further updated through conventional means as discussed above (e.g. erasing the content, replacing the card, etc). The display can be turned “on” and “off’ and the paper card removed when no update information is available.

In yet another embodiment, the retail tags may further include a separate display line that is integrated into the SKU barcode. The display will be activated simultaneously along with new product information to enable an automatic price change when the retail product is checked out.

In yet another embodiment, the retail tags described above may further include an attaching device for securely attaching the retail tag to a product. The tags can also be installed on a shelf edge or a display rack by other attaching devices which may be the same as or different from the attaching devices used to attach the retail tag to a product.

In yet another embodiment, the retail tags can be recycled or reused for multiple retail cycles. For example, the tags are first removed by the retailer, returned to a central point, and then reattached to new retail products. Inspection can be performed and mal-functioning parts replaced, to ensure proper functioning of the tags prior to attachment to new products. A further testing may also be included in the process for recycling the tags.

In yet another embodiment, the retail tags can include the additional function for an Electronic Article Surveillance (EAS) which is used in security to protect merchandise from theft. An alarm is triggered when the product is taken out of the store without first removing the tag. In another embodiment, the power source may be used to enhance the response of the EAS function increasing the probability of detection for an item being stolen.

In yet another embodiment, the elements in the retail tag described above is packaged inside a laminated structure with an opening or window (e.g. a clear area or cut out area) through which a customer can observe the updated information.

In yet another embodiment, patterned electrodes and/or other conductive structures are produced on a first plastic substrate and subsequently transferred to another substrate to facilitate attachment of electronic components. The transfer process can eliminate the via holes associated with conventional attachment processes.

In another embodiment of the present invention, the RFID device of the retail tag has an RFID chip with a temperature sensor. This feature allows the retail tag to operate at a lower voltage, decreasing the cost to maintain the retail tags disclosed in the present invention. Current retail tags in the marketplace if exposed to room temperatures that are either too cold or too hot will not function properly and the display of the RFID device will not change. However, providing an RFID device having a chip with a temperature sensor, allows for the display to change while the item is in a less than favorable environment, because the temperature sensor within the RFID chip is able to sense the surrounding environment and change the display in accordance with a command sent to the RFID device.

Other features and advantages of the present invention will become apparent to those skilled in the art from the following detailed description. It is to be understood, however, that the detailed description of the various embodiments and specific examples, while indicating preferred and other embodiments of the present invention, are given by way of illustration and not limitation. Many changes and modifications within the scope of the present invention may be made without departing from the spirit thereof, and the invention includes all such modifications.

### BRIEF DESCRIPTION OF THE DRAWINGS

These, as well as other objects and advantages of this invention, will be more completely understood and appreciated by referring to the following more detailed description of the presently preferred exemplary embodiments of the invention in conjunction with the accompanying drawings, of which:

FIG. 1 is a schematic view of an retail tag in accordance with one embodiment of the invention;

FIG. 1A is a diagram of a retail tag provided in accordance with one embodiment of the invention;

FIG. 1B is a diagram of a retail tag provided in accordance with one embodiment of the invention;

FIG. 2 is a schematic view depicting exemplary display components of the retail tag in accordance with another embodiment of the invention;

FIG. 2A is a block diagram of the retail tag with a power indicator;

FIG. 2B is a block diagram of the retail tag with a power indicator in a display module;

FIG. 3 is a schematic view of a retail tag provided in accordance with one exemplary embodiment of the present invention;

FIGS. 3A and 3B are block diagrams showing the retail tag with first and second power sources;

FIGS. 4A-4C are block diagrams depicting a process for transferring patterned electrodes or other conductive structures;

FIGS. 4D and 4F are block diagrams illustrating electrical connections between a display driving mechanism and an electrical display for a conventional display.

FIG. 4E is a block diagram illustrating a multiplexed display;

FIG. 5 is a front view depicting a retail tag that includes an electronic display, according to one embodiment;

FIGS. 5A and 5B are a block diagrams illustrating a changeable display;

FIG. 6 is a further view depicting the retail tag of FIG. 5, but with the electronic display displaying an ‘X’;

FIG. 7A is a front view depicting a retail tag, according to another embodiment, with an electronic display displaying an ‘X’, a SKU barcode, and a SKU element;

FIG. 7B is a detailed view depicting the SKU barcode and the SKU element of FIG. 7A;

FIGS. 7C and 7D is a schematic view of the front and back of a retail tag with pricing information and marketing indicia;

FIG. 8 is a front view depicting a retail tag that includes an electronic display, according to yet another embodiment;

FIGS. 8A and 8B are schematic views of the front and back of a retail tag including a pricing history;

FIG. 9 is a front view depicting the retail tag of FIG. 8, but with a price indicia revealed beneath the electronic display;

FIGS. 9A and 9B is a alternate display view of a front and back of a retail tag with the new pricing displayed as a percent off;

FIG. 10 is a front view depicting the retail tag of FIG. 5, but with certain electrical components exposed;

FIGS. 10A and 10B a front view and an insert, respectively of a retail tag illustrating a pocket;

FIGS. 10C and 10D is a view of a retail display system including a combination of a retail item display and a paper card;

FIGS. 11A-11C is a front view of a retail hangtag illustrating an LCD display;

FIG. 12 is a front view depicting a retail tag includes an electronic display, according to another embodiment;

FIGS. 12A and 12B is a front view depicting an electronic display with bar code in an activated and deactivated mode, respectively;

FIG. 13 is a front view depicting a retail tag that includes an electronic display, according to another embodiment;

FIG. 14 is a front view depicting a retail tag that does not include a pricing history of the retail product;

FIG. 15 is a top view depicting a conventional LCD display;

FIG. 16 is a front view depicting a laminated retail tag that includes an electronic display, according to one embodiment;

FIG. 17 is a front view depicting a laminated retail tag that includes an electronic display, according to another embodiment;

FIG. 18 is a front view depicting a laminated retail tag, according to one embodiment;

FIG. 19 is a front view depicting a laminated retail tag according to another embodiment;

FIG. 20 is a front view depicting a laminated retail tag, according to yet another embodiment;

FIG. 21 is a front view depicting a laminated retail tag, according to yet another embodiment;

FIG. 22A depicts a front view of a laminated retail tag according to yet another embodiment; and

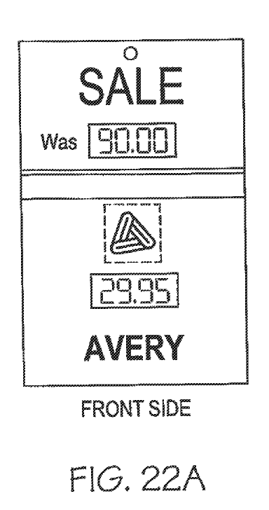

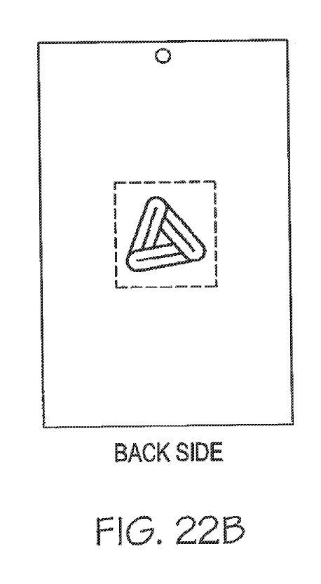

22B depicts a rear view of the laminated retail tag in FIG. 22A.

### DETAILED DESCRIPTION OF THE INVENTION

The apparatuses and methods disclosed in this document are described in detail by way of examples and with reference to the FIGURES. Unless otherwise specified, like numbers in the figures indicate references to the same, similar, or corresponding elements throughout the figures. It will be appreciated that modifications to disclosed and described examples, arrangements, configurations, components, elements, apparatuses, methods, materials, etc. can be made and may be desired for a specific application. In this disclosure, any identification of specific shapes, materials, techniques, arrangements, etc. are either related to a specific example presented or are merely a general description of such a shape, material, technique, arrangement, etc. Identifications of specific details or examples are not intended to be, and should not be, construed as mandatory or limiting unless specifically designated as such. Selected examples of apparatuses and methods are hereinafter disclosed and described in detail with reference made to FIGURES.

Radio frequency identification (RFID) tags and labels (collectively referred to herein as “devices”) are widely used to associate an object with an identification code or other information. RFID devices generally have a combination of antennas, and analog and/or digital electronics, which may include for example communications electronics, data memory, and control logic. For example RFID system often comprise an RFID chip in order to store information. Common uses for RFID tags include but are not limited to security locks in cars, for access control to buildings, and for tracking inventory and parcels.

As noted above, RFID devices are generally categorized as labels or tags. RFID labels are typically pressure sensitive based and have RFID devices that are incorporated into the label, such as by placing an inlay on a label substrate, that are adhesively or otherwise applied or attached directly to objects. RFID tags, such as hangtags, are secured to objects by other means, for example by use of a plastic fastener, string, or other fastening means.

RFID devices include active tags and labels, which include a power source, and passive tags and labels, which do not. In the case of passive devices, in order to retrieve the information from the chip, a “base station” or “activator” sends an excitation signal to the RFID tag or label. The excitation signal energizes the tag or label, and the RFID circuitry transmits the stored information back to the activator. The RFID activator receives and decodes the information from the RFID tag. In general, RFID devices can retain and transmit enough information to uniquely identify individuals, packages, inventory and the like. RFID tags and labels can be characterized as to those (this is a little confusing—I would try to strike out the phrasing “as to those” maybe rephrase to “Information may only be written once to RFID tags and labels and may only be written during usage of the RFID tag/label) to which information is written only once (although the information may be read repeatedly), and those to which information may be written during use. For example, RFID devices may store environmental data (that may be detected by an associated sensor), logistical histories, state data, etc.

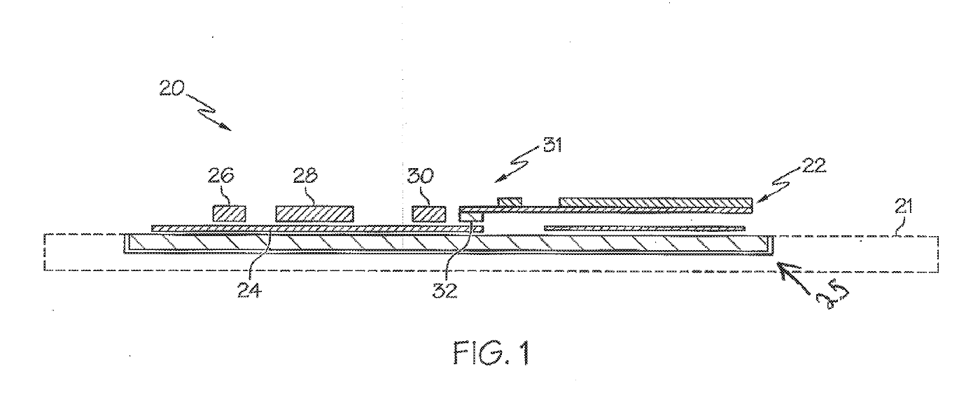

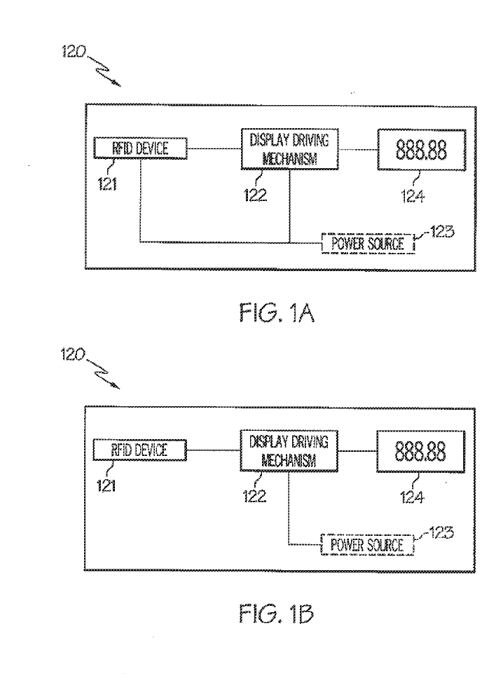

Selected embodiments are hereinafter described in detail in connection with the views and examples of FIGS. 1-22, wherein like numbers indicate the same or corresponding elements throughout the views.

As illustrated in FIG. 1, a retail tag 20 can include a body portion 21 and an electronic display 22 which includes a display medium sandwiched or disposed between two electrodes. The body portion 21 of the retail tag 20 can support the electronic display 22 and can define a viewing window 25 (not shown in FIG. 1) such that the screen of the electronic display 22 is visible to an observer of the retail tag 20. In one embodiment, the retail tag 20 can be appended directly to a product.

In other embodiments, the retail tag 20 can be installed on a shelf edge or a display rack. Product information (e.g., the product's price, its UPC barcode, or a product's applicable discounts) can be displayed on the screen. When the product information requires updating, the screen can be electronically updated such that the screen displays updated product information.

In one exemplary embodiment, the retail tag 20 can be configured to communicate with an external RFID device, such as an RFID activator, to facilitate programming and/or updating the product information displayed upon the screen of the electronic display 22. The RFID activator can establish communication with the retail tag 20 over a radio frequency (RF) communication link. An operator (e.g., a user or a computer) can broadcast or otherwise issue instructions to the retail tag 20 over the RF communication link to facilitate the display of the product information upon the screen. Later, if the product information requires updating, the RFID activator can re-establish communication with the retail tag 20 and can issue additional instructions over the RF communication link to facilitate the updating of the product information. It will be appreciated that when a plurality of retail tags 20 are deployed in an environment, such as a retail store, the RFID activator can communicate with multiple retail tag 20 through selective addressing.

The retail tag 20 can be provided in any of a variety of arrangements that can communicate with the RFID activator or similar device to facilitate programming and/or updating of the electronic display 22. For example, as illustrated in FIG. 1, the retail tag 20 can include a RFID antenna 24, an RFID processor 26, a battery 28, a microcontroller 30, a display driver 31 and an electronic display 22. The microcontroller and the display driver or other similar devices is referred to as display driving mechanism. The RFID antenna 24 can be in electrical communication with the RFID processor 26. The RFID processor can be in communication with the microcontroller 30. The microcontroller 30 provides the information to be updated to the display driver 31. The display driver 31 can be arranged to be in electrical communication coupled with the electronic display 22 via, for example, an ACP connection 32 (shown disconnected from the electronic display 22 in FIG. 1). As described above, an RFID activator can broadcast instructions to the retail tag 20 via RF signals. The RF signals can be received by the RFID antenna 24 and relayed to the RFID processor 26. The RFID processor 26 can transmit the interpreted instructions to the microcontroller 30. The microcontroller 30 can transmit the information to be updated to the display driver 31. The display driver 31 can operate the electronic display 22 to display an image on the screen according to the instructions from the RFID activator.

It can be appreciated that the power source may function as an antenna for the retail tag of the present invention in order to reduce the overall size of the retail tag. Additionally, the can be manipulated in order to function as an antenna for the retail tag.

In another embodiment, the backplane 127 of the retail tag and its corresponding structure can be manipulated in order to function as an antenna.

The battery or power source 28 can power certain of the electrical components of the retail tag 20 to facilitate communication with an RFID activator and to power the electronic display 22. However, in one embodiment, the battery 28 might not power the RFID processor 26 such as when the RFID processor 26 is provided in a passive-type RFID tag arrangement.

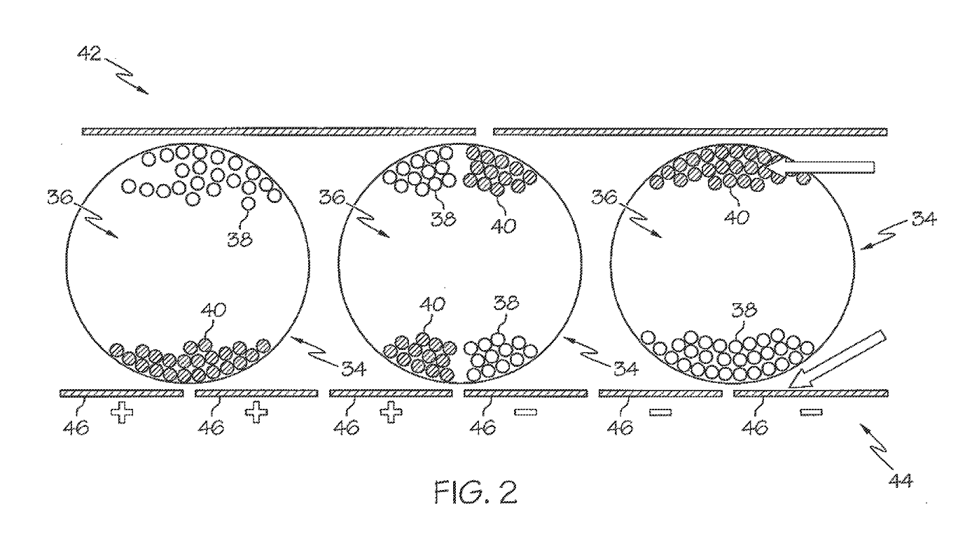

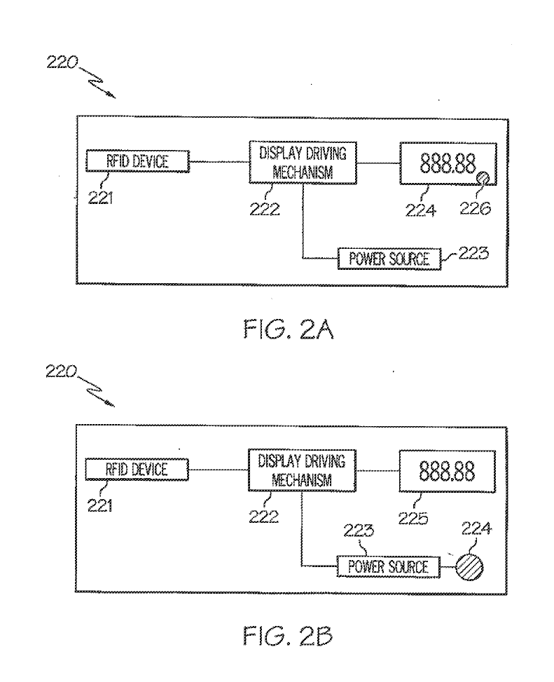

In one exemplary embodiment, the electronic display 22 illustrated in FIG. 1 can comprise an electrophoretic display medium. In such an exemplary embodiment, as illustrated in FIG. 2, the display medium of the electronic display 22 can include a plurality of electrophoretic capsules 34. Each of the electrophoretic capsules 34 can include an electrophoretic composition of dispersion fluid 36 (e.g., clear fluid), white particles 38, and black particles 40. The electrophoretic capsules 34 can be sandwiched between an upper electrode 42 and a lower electrode 44 to form the electronic display. The upper electrode 42 can be transparent. The lower electrode 44 can comprise a composite electrode that includes a plurality of individual electrodes 46, which can cooperate with the upper electrode 42 to induce positive and/or negative charges upon the white and black particles 38, 40 in the electrophoretic capsules 34. The white and black particles 38, 40 can be oppositely charged. Thus, when a positive or negative charge is induced upon the electrophoretic capsules 34, either the white particles 38 or the black particles 40 are activated (e.g., driven towards the upper electrode 42) so that the activated particle 38 or 40 are viewable through the upper electrode 42.

The upper electrode can be transparent, translucent, partially opaque or clear so that the information can be observed through the electrode. However, it is acknowledged that the upper electrode may be colored or partially colored. Alternatively, only portions of the upper electrode may be transparent and other portions are opaque so that only those transparent areas over the display are visible. The bottom electrode can be transparent, translucent, partially opaque or opaque and is segmented to enable a high resolution display.

The display medium of the electronic display 22 includes but not limited to, electrochromic, liquid crystal, electrophoretic materials, etc. The display medium can be passive matrix, active matrix or direct driven. Preferred display module includes a direct driven, paper-like electrophoretic display from E-Ink Corp. (Cambridge, Mass.) or Sipix Imaging Inc. (Fremont, Calif.), an electrochromic display from NTERA Inc. (Radnor, Pa.), or a ChLCD display from Kent Display Inc. (Kent, Ohio).

The electronic display 22 can be configured as a two-dimensional display such that the individual electrodes 46 extend beneath the plurality of electrophoretic capsules 34 in a two-dimensional array. Each individual electrode 46 can be selectively and independently operated to display a two-dimensional, black and white image upon the screen. It will be appreciated that an electrophoretic display can display an image in any of a variety of colors (e.g., in addition to or alternative from black and white) by arranging particles in a variety of colors and/or by using a color filter.

In one embodiment, the RFID processor 26 and the display driving mechanism can comprise respective storage elements that permit storage of instruction from the RFID activator to facilitate effective operation of the electronic display 22. In another embodiment, the display driving mechanism can include a charge pump that can ensure proper operation of the individual electrodes 46 by ensuring proper signal voltage to positively or negatively charge each individual electrode 46.

The RFID activator can be either portable or fixed in the retail infrastructure. As described above, the RFID device 20 interacts with the external RFID activator over a radio frequency (RF) communication link to update the tracking and pricing information related to the retail product. One skilled in the art can appreciate that the RFID device can operate at any frequencies ranging from KHz to GHz, the one operated under UHF frequency (860 MHz to 960 MHz) is preferred to leverage the existing RFID tracking systems built in the retail stores. It should be understood that suitable frequencies may include high frequency (HF) and low frequency (LF). It will be appreciated that when a plurality of retail tags 20 are deployed in an environment, such as in a retail store, the external RFID activator can communicate with multiple retail labels simultaneously 20 through selective addressing.

The microcontroller 30 and a display driver 31 or similar devices is referred to as display driving mechanism. The microcontroller 30 and the display driver 31 can be either as separate entities or integrated into a single device. The display driving mechanism may further include a storage element to temporarily or permanently store the information related to the retail product. The display driving mechanism communicates with the RFID device, storing some information in the storage element and transferring the updated product and/or pricing information to the electronic display 22. If necessary, an analog to digital signal converting element may be included to convert the radio frequency (RF) signal from the RFID device to digital signal for processing by the display driving mechanism. If necessary, the display driving mechanism may further include a charge pump to provide the voltage level necessary for activating the display module.

Alternatively, the RFID processor 26 and the microcontroller 30 can be integrated into a single component which is electrically connected to a standalone display driver 31, which interacts with the external RFID activator to provide updated information about the retail product to the electronic display 22.

The power source 28 provides power to the retail label. In one embodiment, the power source 28 includes a battery. Suitable batteries include thin film lithium battery and coin cell battery with 1.5 volt or 3.0 volt output. In another embodiment, the power source 28 includes a super capacitor that can harvest the RF energy from the surrounding environment, and/or from the RFID activator. While the RFID activator in this invention is aimed to provide updated information to the retail label 20 and the RF energy can be harvested during the process, one skilled in the art can appreciate that the RFID activator can be used to supply the RF energy to be collected by the super capacitor (power source 28) without sending the updated information. The super capacitor can also be used to charge the battery when additional energy is required to drive functions supported by the battery or primary power source 28.

Reference is now directed to FIGS. 1A and 1B which show block diagrams illustrating the tag 120 having a power source 123 connected to either all of the components of the tag (RFID device 121, display driving mechanism 122) or to only selected components [maybe here say which figure you are referring to FIG. 1a or 1 b). The connection of the power source 123 to the RFID device 121 can enhance the strength of the RF transmission signal and consequently, the coupling distance between the external RFID activator and the retail tag 120. Alternatively, the power source 123 can be connected to only selected components as provided in FIG. 1B where the battery 123 is connected only the display driving mechanism 122.

The external RFID activator may include a portable activator that is able to be carried by the employee and/or customer. Through interaction with the retail tag, a customer can download updated pricing from the retail store as well as additional features about a particular product. Alternatively the RFID activator can be fixed to a store infrastructure or includes a satellite communication system, etc. Exemplary portable RFID activators include portable RFID transreceivers, near field communication devices, etc.

In a further embodiment of the present invention, the RFID device 121 comprises a chip having a temperature sensor in the chip. This allows items to be programmed in an uncontrolled environment. The RFID device with a chip having a temperature sensor is able to operate at a lower voltage. If a command is received by the RFID device within the retail tag, and the retail tag is surrounded by an environment below the operational temperature of the retail tag, the data is saved by the chip having a temperature sensor of the RFID device. The information is saved by the chip until the temperature of the surrounding environment of the retail tag increases to an operational temperature in which the retail tag can display the comma.

In yet another embodiment, the retail tag 220 further includes a power level indicator 226 (FIGS. 2A and 2B), to determine and display the level of the power remaining in the power source 223. The power indicator 226 can be shown in the same display screen 224 as the pricing information (FIG. 2A) or in a separate display screen 224 (FIG. 2B). When a separate display screen 224 is used, a different display medium and driving mechanism 222 may be used. For example, an electrophoretic display can be used to provide updated pricing information and a LED can be used to illustrate the power level 224, 226 of the power source 223. In addition, the power level indicator 224, 226 may function alternatively between “on” and “off” position, or on as needed basis to reduce the power consumption.

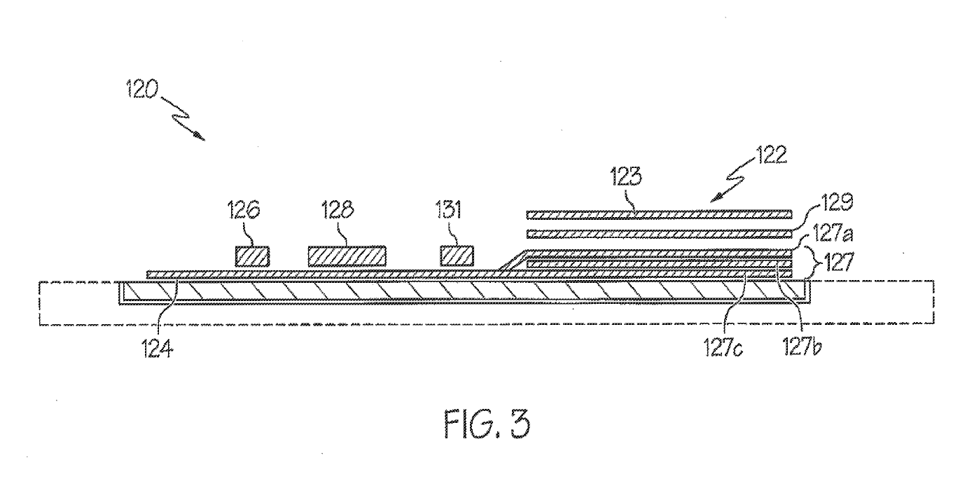

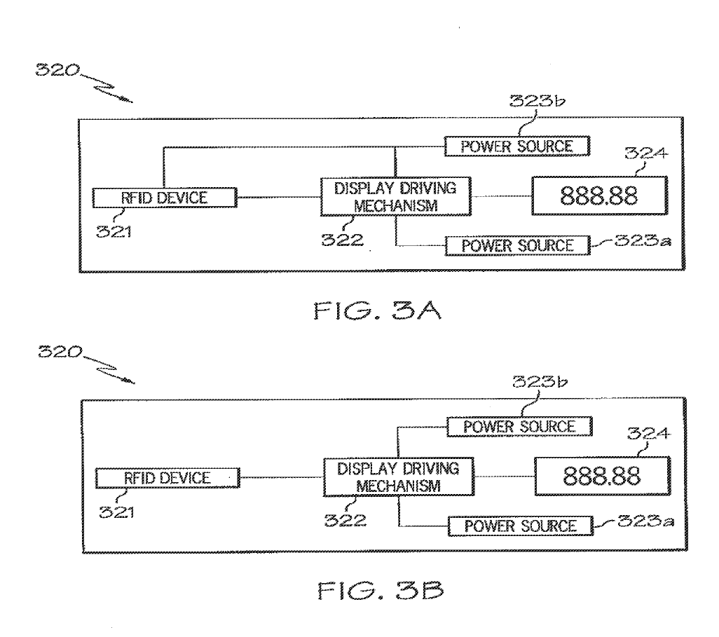

As illustrated in FIG. 3, an alternative embodiment of a retail tag 120 can be provided that is similar in many respects to the retail tag 20 described above and illustrated in FIG. 1. For example, the retail tag 120 can include an electronic display 122, an RFID antenna 24, an RFID processor 126, a battery 128, and a display driving mechanism 131. The electronic display 122 however, can comprise a display film 123 that can be coupled with a printed backplane 127 by way of an adhesive 129. The printed backplane 127 can include an upper conducting layer 127a, an insulating layer 127b, and a lower conducting layer 127c. In one embodiment, the RFID antenna 124, the upper conducting layer 127a, the insulating layer 127b, and the lower conducting layer 127c can be constructed on a flexible substrate such as through a printing process. It will be appreciated that any of a variety of suitable alternative electronic displays can be additionally or alternatively employed in a retail tag, such as for example, an electrophoretic, a liquid crystal display, or an electrochromic display.

An electronic display (e.g., 22, 122) can, in some embodiments, comprise a bistable display such that information displayed upon the display film (e.g. 123—I thought 123 was the power source according to FIG. 1a) remains even if power is no longer being provided to the electronic display (e.g., after power from the battery 28, 128 is insufficient to power the electronic display 22, 122). However, the displayed information can grow faint gradually after long period of use without power. Suitable bi-stable display medium includes an electrophoretic display or ChLCD display. In another embodiment, however, an electronic display (22, 122) can comprise a non-bistable display, such as a twisted nematic (TN) LCD or electrochromic display. In such an embodiment, if power from a battery is insufficient to power an electronic display, the displayed information can grow faint quickly or disappears completely. To maintain the display or the display quality, a retail tag can include a redundant battery that is configured to power an electronic display if power from a primary battery (e.g., 28, 128) is no longer sufficient to power the electronic display (22, 122). This is particularly important for non-bistable displays which can stop displaying information. Non-bistable displays can be easier to manufacture and more cost efficient than bistable displays. Therefore, implementation of a redundant battery on a retail tag (e.g., 20, 120) can allow for the use of a non-bistable display in environments in which bistable displays are oftentimes implemented.

Accordingly, in another embodiment, the retail tag 320 includes first and second power sources 323a, 323b (FIGS. 3A and 3B) which are intended to extend the battery life and/or to ensure the normal function of the display module 324 even if the primary power 323a source failed. The first and second power source 323a, 323b can be the same, such as battery or super capacitor, or a combination of a battery and a super capacitor.

Continuing with the discussion of FIGS. 3A and 3B the power source or at least one power source of the above retail tag is coupled to the display driving mechanism 322, but not to the RFID device 321. Such arrangement can reduce the power consumption of the power source 323a, 323b. However, one skilled in the art can appreciate that the power source 323a, 323b or at least one power source of the above retail tags can be coupled both to the RFID device 321 and the display driving mechanism 322 to provide power to each of these devices (FIG. 3A). Such connection can enhance the RF signal strength and extend the working distance of the RFID device.

### Process of Making the Retail Labels

Connecting the display driving mechanism to the electronic display has been a big challenge to display industries. Conventionally, electrical attachment of a display driving mechanism to the bottom segmented electrode of the electronic display has been achieved via holes as described, for example, in U.S. Pat. No. 7,304,780 and US published application US 2008/0061300 which are referred to throughout this disclosure. A plastic substrate, such as a polyimide or PET, is used having a patterned electrode layer on one surface and an electrical circuit or electrical wires on the opposite surface. The patterned electrode and the electrical circuit or wires can be made by etching or printing. Blind via holes positioned to correspond to individual segmented electrodes are formed through the plastic substrate and establishes electrical connection between the segmented electrode and the display driving mechanism.

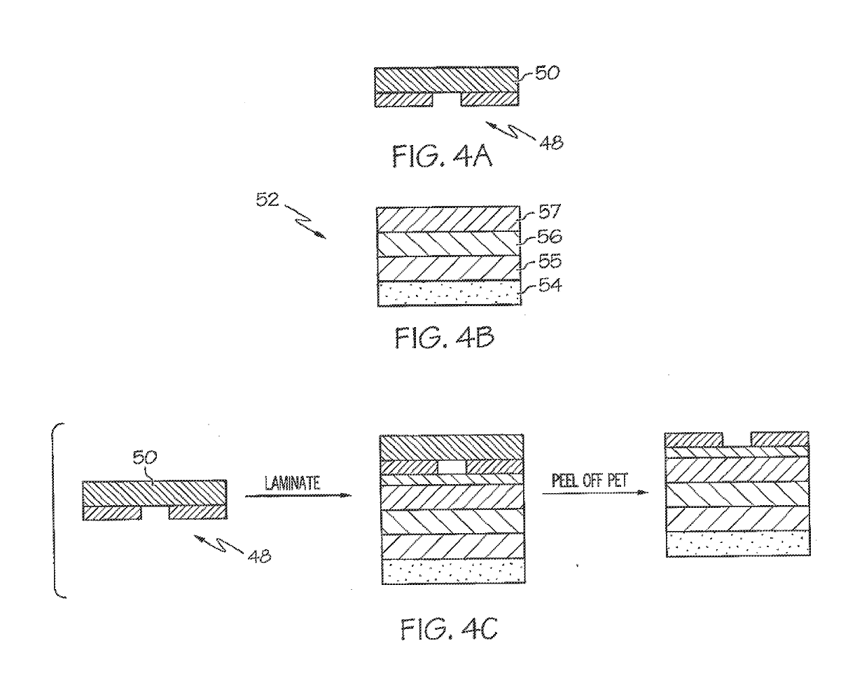

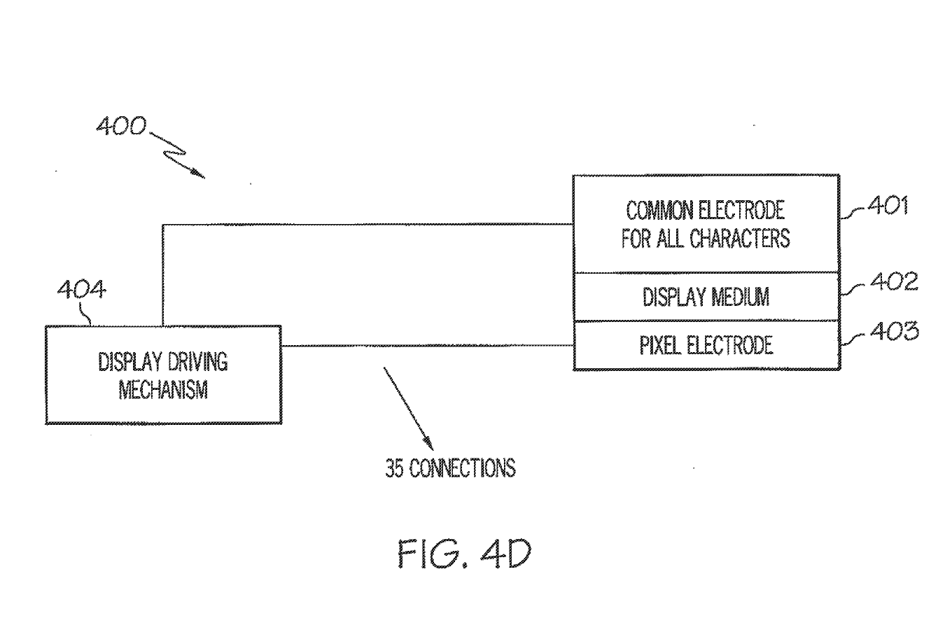

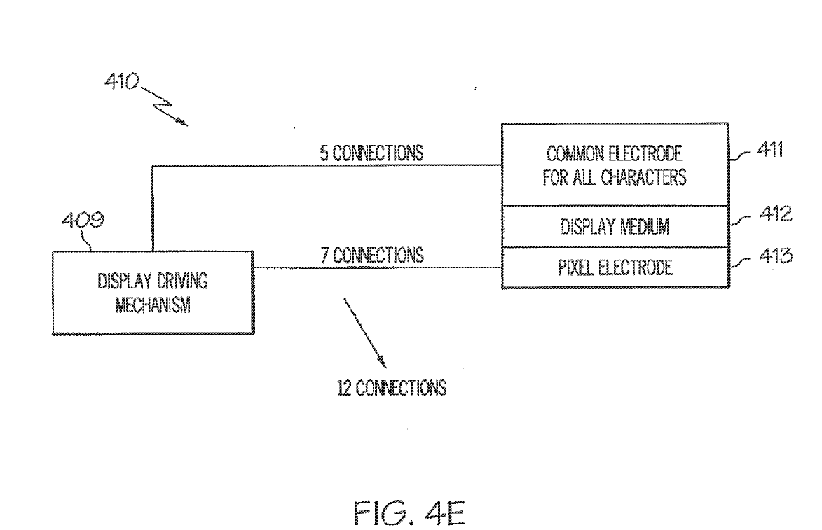

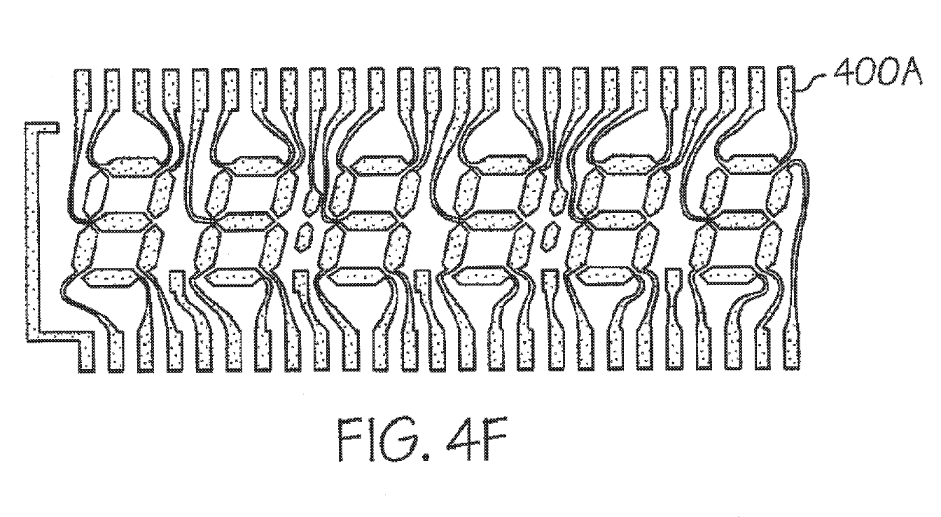

The creation of holes on a substrate (e.g., polyimide or PET) and subsequent printing of conductive traces within the via holes can be relatively expensive and time intensive due to the need for accurate alignment. However, the embodiment in FIGS. 4A-4C illustrates a transfer process for electrically attaching a display driving mechanism to an electronic display without the use of holes. As illustrated in FIG. 4A, a patterned electrode 48 can be created on a PET substrate 50 by printing or etching, for example. As illustrated in FIG. 4B, a front panel 52 can be provided that includes a PET layer 54, a common electrode 55, a display medium 56, and an adhesive layer 57. As illustrated in FIG. 4C), the patterned electrode 48 can be attached to the adhesive layer 57. In one example, as illustrated in FIG. 4B, the adhesive layer 57 can be formed on the front panel 52 to facilitate attachment of the patterned electrode 48. However, in an alternative example, the adhesive layer 57 can be formed upon the patterned electrode 48 (e.g., through application of firm coating adhesive over the patterned electrode 48 prior to the attachment of the patterned electrode to the front panel 52). As further illustrated in FIG. 4C, the PET substrate 50 can be peeled away or otherwise removed to expose the patterned electrodes 48. The exposed surface of the patterned electrode 48 can be connected to a high density pitch connecting terminal or directly to a display driving mechanism (e.g., 31), to form a display device.

Transferring the patterned electrode 48 to the front panel 52 from the PET substrate 50 (as described above with reference to FIGS. 4A-4C) can be accomplished without increasing the dielectric materials between the common electrode 55 and the patterned electrode 48. Additionally, forming the patterned electrode 48 on the PET substrate 50 can be effective for manufacturing the patterned electrode 48 using a roll-to-roll process. It will be appreciated that in one embodiment, the PET substrate 50 can be formed from a reusable material thereby reducing waste and cost during production of an electronic display.

It will be appreciated that other conductive structures can be created on the same substrate as the patterned electrode 48. For example, an RFID antenna (e.g., 24) can be created on a PET substrate such as by etching or printing. In such an arrangement, the patterned electrodes 48 can first be transferred to the front panel display 50 to create an electronic display. Next, the electronic display and the RFID antenna can be transferred to another flexible substrate that carries the driving circuits and other electronic components. It will also be appreciated that when an electrophoretic display is used, the patterned electrode 48 can include a moisture barrier layer or a sealing layer (e.g., a sealing layer can be attached to the patterned electrode 48).

It will be appreciated that in some embodiments, an electronic display (e.g. 22, 122) can be provided as the sole means for displaying information on a retail tag 20 (e.g., as a standalone display). It is appreciated however, that in other embodiments, an electronic display can be provided in a retail tag alongside other pre-printed product information that cannot be updated via the external RFID activator.

In the foregoing exemplary embodiment, a direct driven segmented electronic display is arranged to reduce the number of electrical connections between the electronic display and the display driving mechanism and consequently, to reduce the physical dimension of the display driving mechanism and the number of conductive traces. A conventional direct driven segmented display (FIGS. 4D and 4F) comprises a transparent common electrode which is continuous, a display medium, a patterned electrode beneath the display medium, a pixel electrode 403, and a display driving mechanism 404. In such display, each digit requires seven (7) connections to produce the basic numerical character Therefore to display a five (5) digit numerical pricing information requires thirty five (35) connections. For a retail tag with 3 rows, 5 digit numerical display, it requires 105 connections plus 1 extra connection to the common electrode and 1 extra connection to the ground. All these connections have to work at the same time which raises the manufacturing complexity and reduces the product yield. With a fixed width of the contacting lines and pitch between two adjacent contacting lines, a higher number of connections translates into a larger size and higher cost display driving mechanism 404.

To reduce the number of connections, the electronic display 410 is multiplexed as shown in FIG. 4E. The multiplex comprising a common electrode for each character 411, a display medium 412, and a pixel electrode 413. A single row, 5 digit display requires a only 12 connections: 5 connections to the common electrode 411 and 7 connections between the display driving mechanism 409 and the pixel electrode 413. The display medium 412 is connected to both the common electrode 411 and the pixel electrode 413. For an electronic display with several rows of digit information, a single row would be activated and only the segments under this row would control the display with the digits being updated one at a time. This configuration allows all row segments to be connected in parallel with the patterned electrode controlling which row is active. For a retail tag with three rows of five digit numerical pricing information, only thirty six connections are necessary plus one common background.

To make such a new display, a patterned top electrode is used to partition the display into rows which may be individually controlled to allow the complete display to be multiplexed. The patterned electrode can be made by conventional patterning techniques such as lithography or by deposition through a mask. The patterned electrode is processed in such a way as to produce rows which correspond to the final cut display material so that a three row display would have three corresponding strips of conductor.

Multiplexing is particularly advantageous for the retail label having more pricing information or digits, either in one row or in more than one row. Since the digits are updated one at a time, in contrast to a conventional display where all the digits are updated simultaneously, the multiplexed display takes more time to update the pricing information.

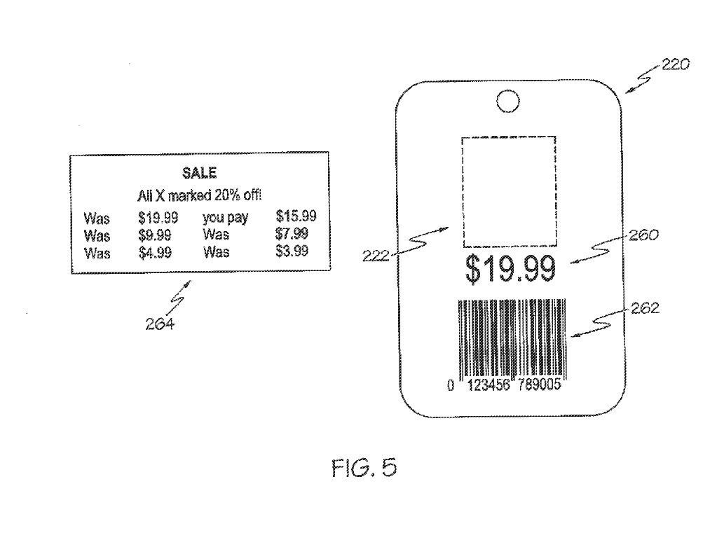

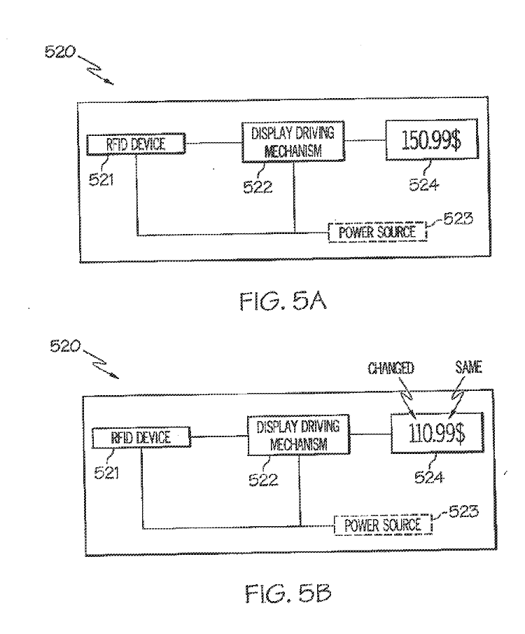

In another arrangement, at least one of the digits in the electronic display described above can be kept constant and not updateable by the RFID activator (FIG. 5). Referring to FIG. 5b an electronic display 524 comprises a five digit sale price of 150.99$. As discussed above, in order to display all five digit numbers, thirty-five electrical connections have to be made between the display driving mechanism and the pixel electrode of the electronic display. When the two digit “99” in the retail tag 520 are “frozen” and not electrically connected to the display driving mechanism, as many as fourteen electrical connections can be eliminated. Referring to FIG. 5a, the sale price of the retail product can be changed from “$150.99” to “$110.99” or any other price combination e.g. “$xxx.99.” For such high price products, any changes at the cent level do not have big impact to the final price. Even for lower price products, many are still shown as “$xxx.99” to leverage the psychological effect to allure customers. Thus, by freezing at least one digit in the pricing information, a significant reduction in the electrical connections can be realized, and the advantage becomes even more evident for electronic displays with more rows in the display.

The electronic display shown in retail tag 520 can be made in different ways. For example, with a bi-stable display medium which can sustain the display digits without power. The display medium can be placed or passed between a common electrode and a pixel electrode having “$0.99” or “$0.88” configuration. When an electric field is applied across the two electrodes, the “$0.99” will be created on the display medium and maintained after the medium is removed from or passed away from the electrodes. The three digits forming the dollar amount (e.g. 150) can be formed according to the conventional direct driven display, by electrically connecting pixel electrodes to the display driving mechanism. Alternatively, the “$0.99” can be printed by conventional or digital printing techniques using water based, solvent based, or UV curable inks. In both cases, the RFID activator can be programmed to change the pricing information only at dollar amount and not the cent amount. Through appropriate electrical connections, any numbers or letters in the electronic display of the retail tag 520 can be made updateable or non-updateable, e.g. frozen.

In yet another embodiment, the electronic display in retail tag 520 can be further made to display a new pricing information with at least one frozen digit or without showing the frozen digit at all, e.g. a partially-customizable electronic display. For example, the sale price of the retail product can be changed from “$150.99” to either “$110.99” (or any other price combination e.g. “$xxx.99”) or 110 (or any other price combination xxx). This can be achieved by printing the display medium and the bottom electrode in the shape of “$0.99” by conventional or digital printing techniques. The printed bottom electrode, which is a single segment, is electrically connected to the display driving mechanism. The display driving mechanism can be programmed to either display the “$0.99” or without display the “$0.99”. When the display driving mechanism is programmed to display the “$0.99”, the retail product can be changed to “$xxx.99.” When the display driving mechanism is programmed to not display the “$0.99”, the new price will be displayed as “xxx.” Because the “$0.99” is electrically connected to the display driving mechanism, both bi-stable or non-bistable display medium described above can be used and good display quality can be maintained.

In yet another embodiment, the retail tag 520 is arranged to display the new pricing information as percentage off (e.g. “50% OFF”) or the like depending on the requirements of the retailer. When new price information is not available, the electronic display exhibits “% OFF!”, “0% OFF!”, or “00% FF!”. The “% OFF!” can be achieved by printing or by using a bi-stable display medium which is not electrically connected to the display driving mechanism, as discussed above for retail tag 520. When a new pricing information is available according to instructions from the external RFID activator, the display module displays “50% OFF!” or any combination of “xx % OFF!” in the electronic display. Since only two digits or sixteen electrical connections (fourteen connections for the two digits, plus one connection for the common electrode, and one connection for the ground) are needed to display the new pricing information, regardless of the initial pricing, this arrangement can significantly reduce the physical dimension of the display mechanism, simplify the assembly process, and enhance the assembly yield.

The “OFF %” can also made by printing a display medium using conventional or digital printing techniques and be made invisible when no new pricing is available. For example, the sale price of the retail product can be changed from “$150.99” to “50% OFF!” or any other percentage combination e.g. “xx % OFF!.” When no new price information is available, the electronic display can exhibit “% OFF!”, “OFF %!”, “0 OFF %!”, “00 OFF %!” or exhibit the same background color as the printed portion and is invisible to the customer. This can be achieved by printing the display medium and the bottom electrode in the shape of “% OFF!” by conventional or digital printing techniques. The printed bottom electrode, which is a single segment, is electrically connected to the display driving mechanism. When the display driving mechanism is programmed to display the “OFF %”, the retail product can be changed to “x OFF %!” or “xx OFF %!”. When the display driving mechanism is programmed to not display the “OFF %!”, the electronic display will exhibit the same background color as the printed information and is invisible to the customer. Because the “OFF %!” is electrically connected to the display driving mechanism, both bi-stable or non-bistable display medium described above can be used and good display quality can be maintained.

One skilled in the art can appreciate that in addition to new pricing digits or “OFF %!” as discussed above, extra information such as image or text information can be printed around the pricing information using either non-customizable or partially-customizable processes.

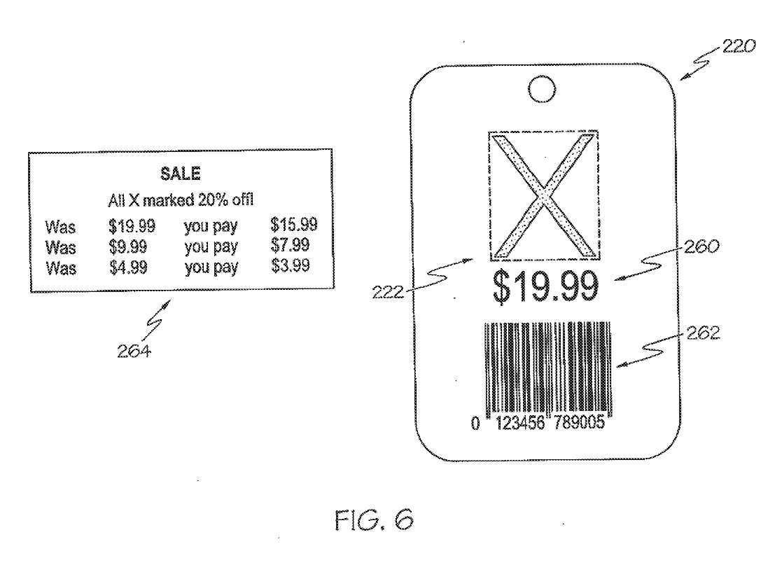

In one embodiment, as illustrated in FIGS. 5 and 6 (this seems like it would go earlier in the description), a hybrid retail system is shown comprising a retail tag 220 and a printed card 264. The retail tag 220 includes an electronic display 222 that is provided alongside a price indicia 260 and a SKU barcode 262. The price indicia 260 and SKU barcode 262 can be preprinted on the retail tag 220 either by conventional or by digital printing techniques using water based, solvent based or UV curable inks. The electronic display 222 can be alternated between a deactivated state (as illustrated in FIG. 5) and an activated state (as illustrated in FIG. 6). When the electronic display 222 is in the deactivated state, the electronic display appears the same color as the retail tag 220 (e.g., white). When the electronic display 222 is alternated to the activated state, a colored ‘X’ appears above the price indicia 260 and SKU barcode 262. The electronic display 222 therefore can be selectively alternated between the deactivated state and the activated state to facilitate a price change for an associated retail item.

The electronic display 222 is activated to alter the price of the associated retail item and deactivated to return to the initial price of the associated retail item. A printed card 264 can be placed near a retail item to assist a consumer with integrating the price of the retail item. In one example, if the retail item is to be sold at the amount indicated by the price indicia 260 (e.g., “$19.99”), the electronic display 222 is deactivated such that the ‘X’ is not visible to a consumer. However, when the retail item is to be sold according to the discounts displayed on the printed card 264, the electronic display 222 can be alternated to the activated state such that the ‘X’ is visible. The visible ‘X’ can direct the consumer to the printed card 264 to determine the accurate price of the retail item. Since the “X” involves only four electrical connections between the display driving mechanism (not shown) and the electronic display, this arrangement provides a lower cost solution for alternating the price information.

FIGS. 5A and 5B provide a block diagram showing the retail tag 520 being updated from a first display 524 in FIG. 5A to a second display 524 in FIG. 5B. In each diagram, a power source 523, may or may not be provided to power the tag 520. In each instance, an RFID device 521 is attached to a power source 523 if provided as well as the display driving mechanism 522 which provides the information to change the display 524.

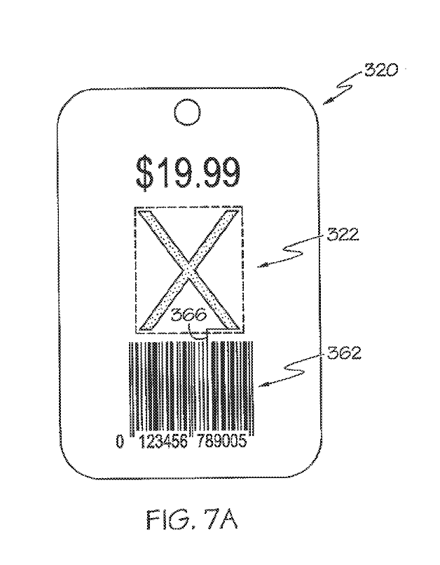

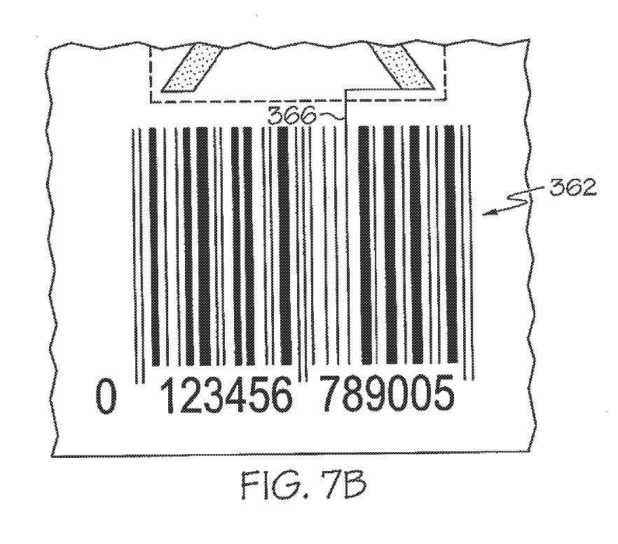

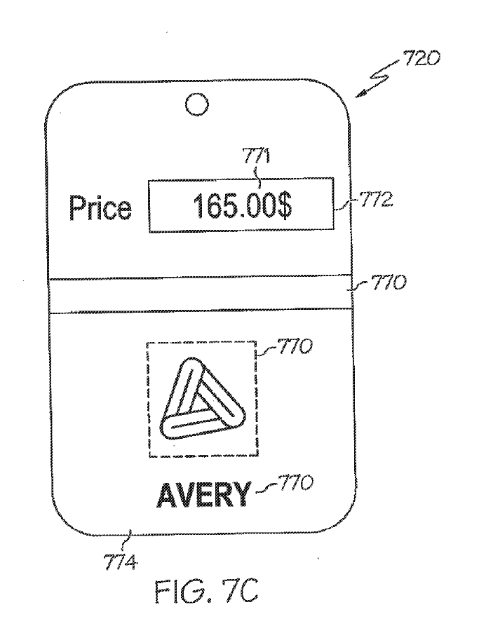

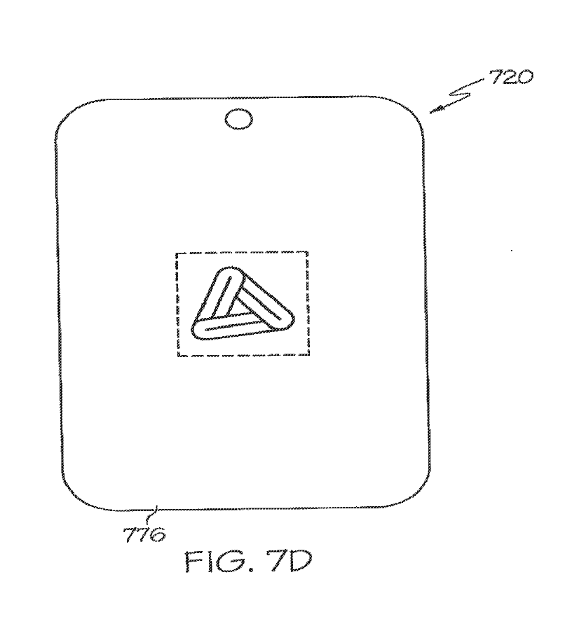

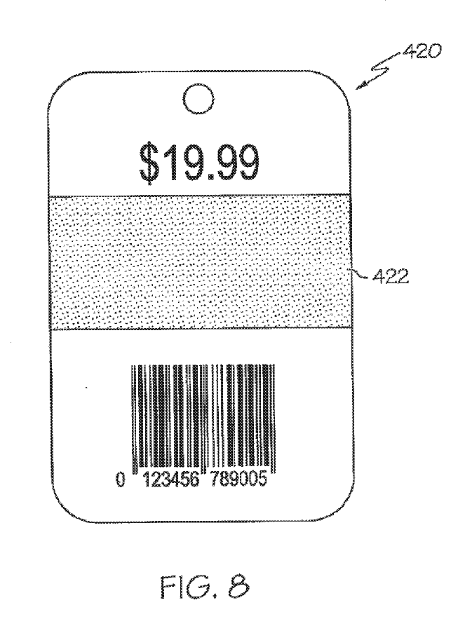

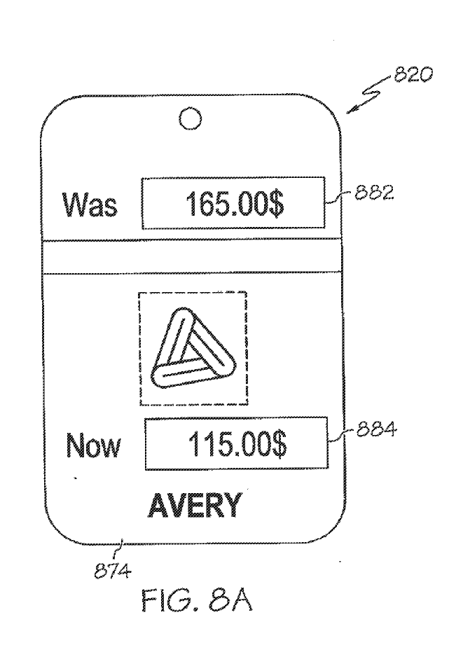

In another embodiment, as illustrated in FIGS. 7A and 7B, a retail tag 320 and an electronic display 322 can be provided that are similar in many respects to the retail tag 220 and the electronic display 222 illustrated in FIGS. 5 and 6. For example, the electronic display 322 can be alternated between a deactivated state and an activated state to selectively display a visible ‘X’ on the retail tag 320. However, the retail tag 320 can further include a selectively alterable SKU bar 362. The electronic display 322 can further include a SKU element 366 that can be selectively displayed when the electronic display 322 is alternated to the activated state. The SKU element 366 can extend within the SKU barcode 362 to alter the SKU information displayed by the SKU barcode 362. Thus, when the electronic display 322 is alternated to its active state, a visual ‘X’ is provided to the customer to indicate an applicable discount, and the SKU barcode 362 is also altered to reflect the applicable discount when the retail tag 320 is scanned at a point-of-sale terminal.

FIGS. 7C and 7D illustrate the front side and back side 776 of a retail tag 720 of the present invention with pricing information 771 and marking indicia 770 on the front and back of the retail tag 720. The electronic display 772 of the retail tag 720 displays pricing information 771.

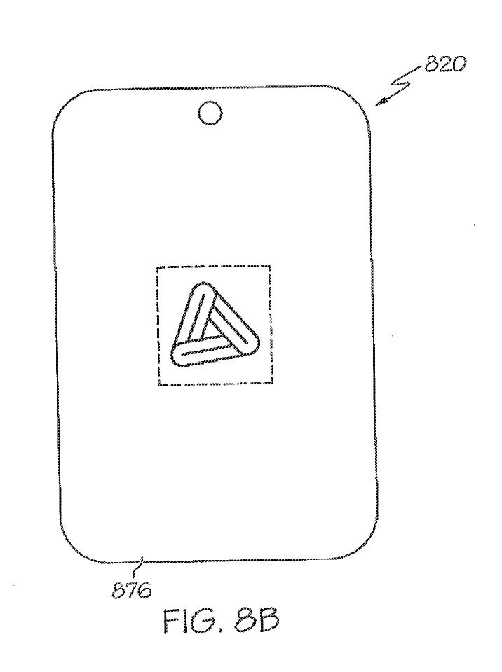

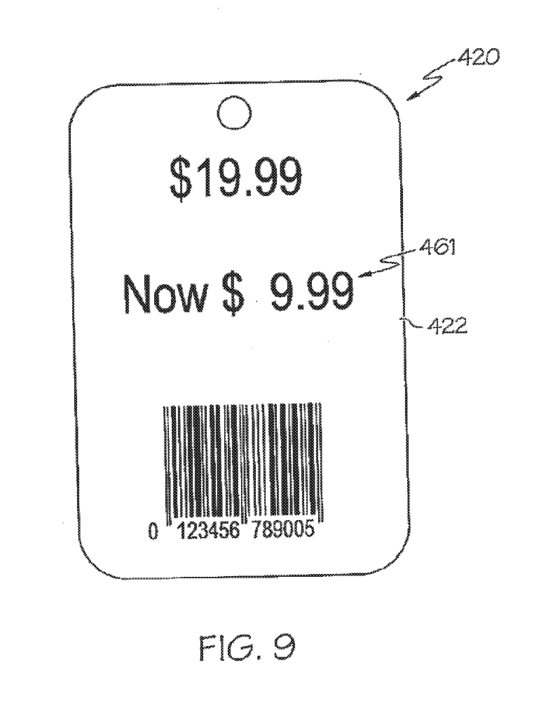

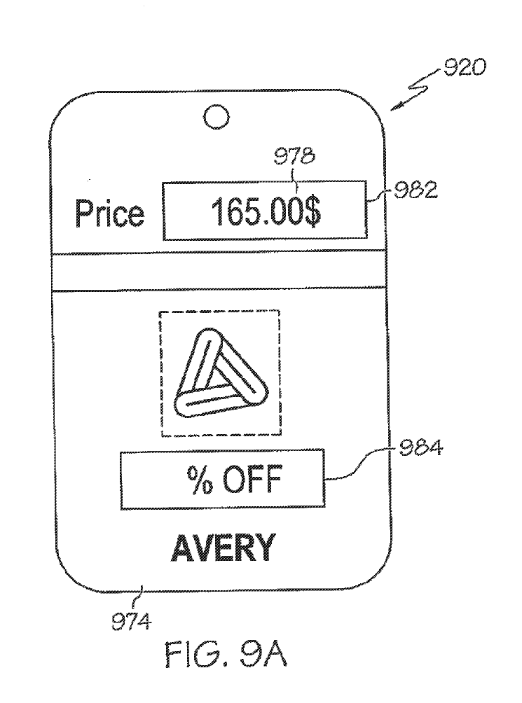

In another embodiment, as illustrated in FIGS. 8 and 9, a retail tag 420 and an electronic display 422 can be provided that are similar in many respects to the retail tag 220 and the electronic display 222 illustrated in FIGS. 5 and 6. For example, the electronic display 422 can be alternated between a deactivated state and an activated state. However, when the electronic display 422 is in the deactivated state, as illustrated in FIG. 8, the electronic display 422 displays a rectangular black block upon the retail tag 420. When the electronic display 422 is alternated to the activated state, as illustrated in FIG. 9, the electronic display 422 appears as a rectangular block that is the same color as the retail tag 420. An alternative price indicia 461 can be preprinted on the retail tag 420 beneath the electronic display 422 such that when the electronic display 422 is alternated to the activated state, the alternative price indicia 461 is visible (e.g., to indicate a different price to a customer).

In another embodiment, FIGS. 9A and 9B illustrate the front and back of a retail tag 920. The electronic display 982 displays price information 978 in addition to a percentage off 984 the price 978. The back side 976 of the retail tag 920 may also display information similar to the front side of the retail tag.

It will be appreciated that the electronic displays 222, 322, 422 can be alternated between their deactivated and activated states with an RFID activator and can thus be configured similarly to retail tags 20, 120 to facilitate communication with the RFID activator. However, since the electronic displays 222 (this is the display driving mechanism), 322, 422 involve many fewer electrical connections between the electronic display and the display driving mechanism, the retail tags 220, 320, 420 can be much less complex than the retail tags 20, 120 illustrated in FIGS. 1 and 3.

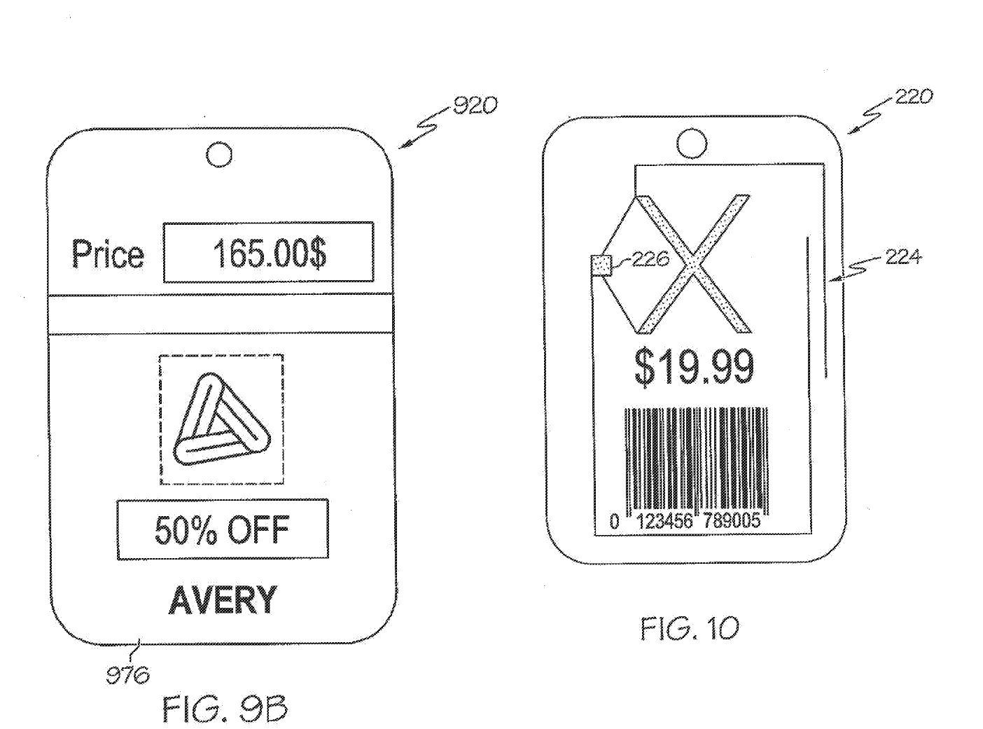

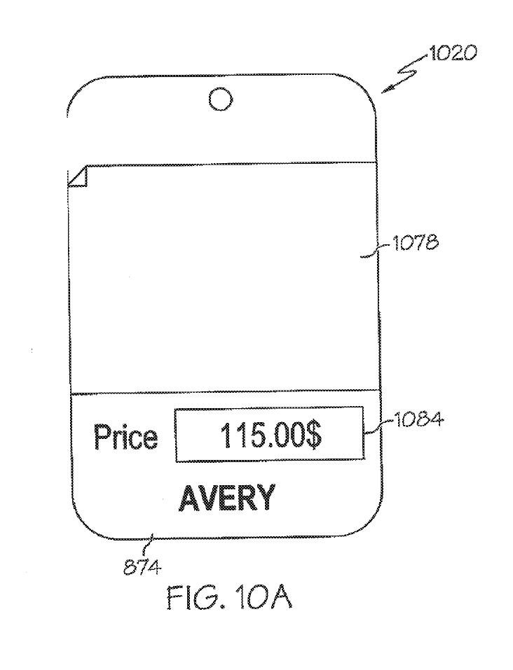

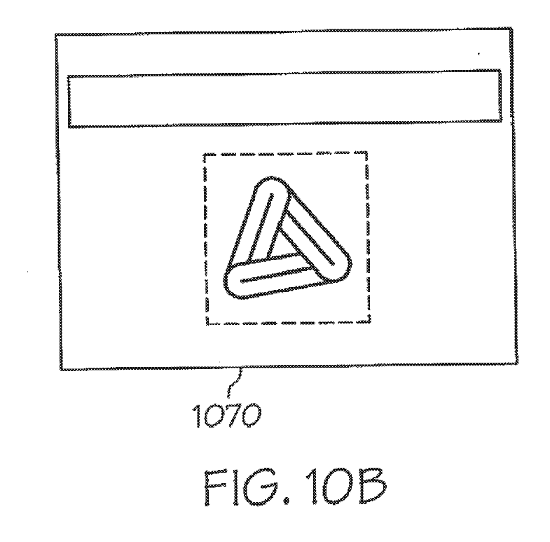

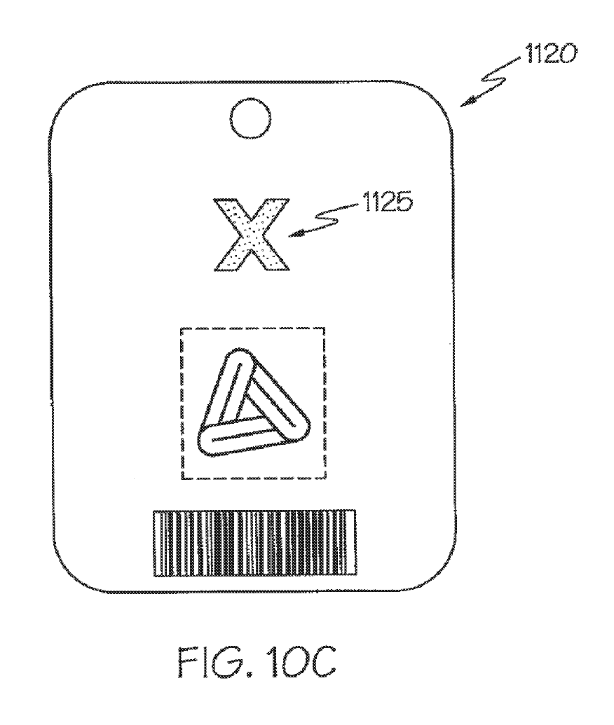

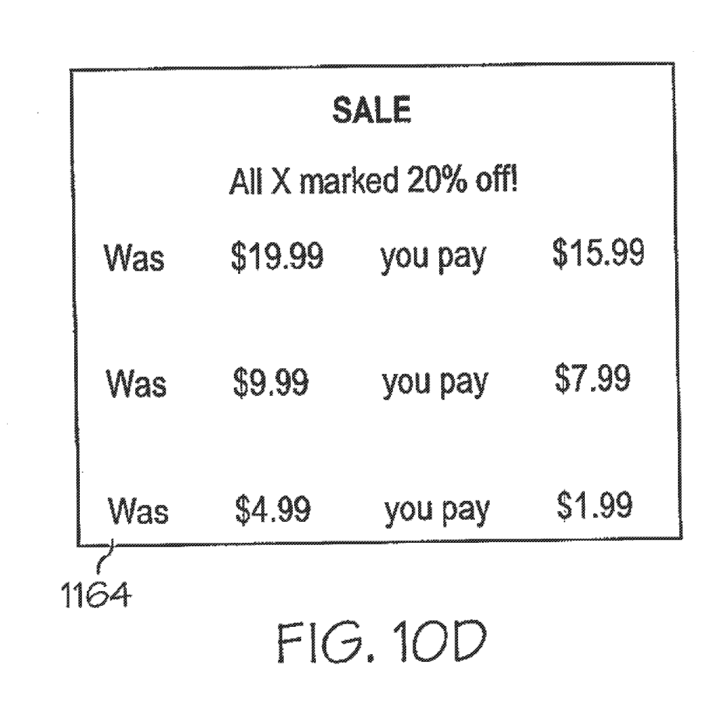

For example, as illustrated in FIG. 10, the retail tag 220 can include an RFID antenna 224 and an RFID processor 226. The RFID processor 226 can include a voltage driver (not shown) and can be coupled with the RFID antenna 224. The RFID processor 226 can interpret instructions broadcast from an RFID activator via RF signals received at the RFID antenna 224. Based on the instructions, the RFID processor 226 can communicate with the voltage driver to alternate the electronic display 222 between the activated and deactivated states. The RFID antenna 224, the RFID processor 226, and the voltage driver can provide a compact, efficient, cost effective solution for effecting a price change on a retail tag. In addition, in an embodiment where the RFID antenna 224, the RFID processor 226, and the voltage driver are implemented as an integrated circuit, only three bumps (e.g., RF, GND, Drive) would need to be provided on the integrated circuit. Such an arrangement can facilitate a more simplified assembly for the retail tag 222 (this is the display driving mechanism per FIG. 2a NOT the retail tag which is 220—should probably make ref to this in FIG. 10. It will similarly be appreciated that since the electronic displays 222, 322, 422 have a discrete number of states (e.g., two), the connections to a voltage divider can be reduced, which could result in a more cost-efficient, lighter-weight electronic display.

FIGS. 10A and 10B provide an additional feature of the present invention, in which a pocket area 1078 can be provided to hold a marketing card or insert 1070. The card or insert 1070 can be placed within the pocket, which may be clear, transparent or translucent to allow a prospective customer to view the card. The card 1070 can be used to identify the particular garment or article to which the price tag 1020 is attached and in that way, a tag 1020 can be reusable and interchangeable with other goods merely by changing the card 1070 and inserting different cards into the pocket 1078. The display 1084 can then be updated based on the change related to the card 1070.

In accordance with yet another embodiment, a retail tag comprises at least one customizable portion and at least one non-customizable portion. The customizable portion is configured to display an image that can be updated according to instructions from the RFID activator. The non-customizable portion is configured to selectively display an image, such as a printed image. FIGS. 8A and 8B provide an example of a retail tag 820 having at least one customizable portion and at least one non-customizable portion. The retail tag 820 has the front surface 874 and back surface 876 and comprises the first, non-customizable price display 882 and the second, customizable price display 884. As will be appreciated, other information can be displayed in the display blocks 882 and 884.

FIGS. 10C and 10D show a paper label 1120 in combination with a wireless sign or other retail display 1164 showing updatable pricing information. In this manner, a particular printed indicia 1125 can be used by a consumer to check the prices that are displayed on a sign or tag 1164.

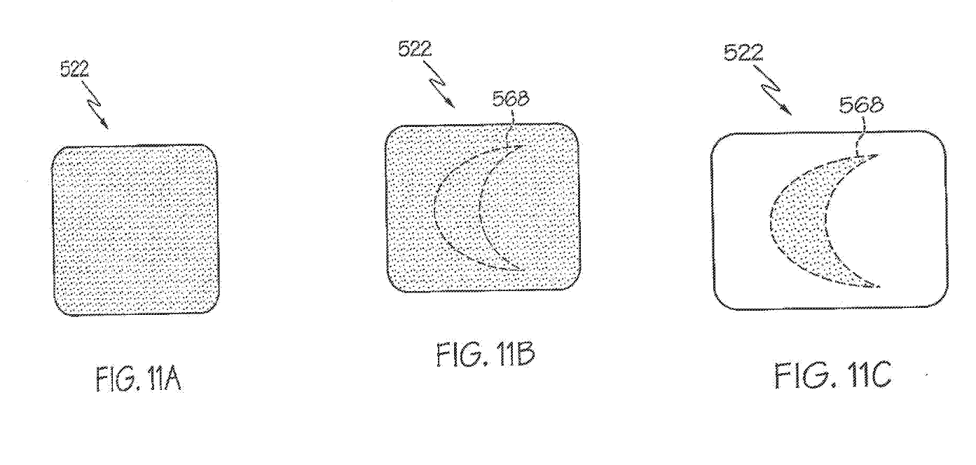

It will be appreciated that an electronic display (e.g., 222, 322, 422) can be configured in any of a variety of manners that facilitate operation between an activated and deactivated state. For example, with reference to FIGS. 11A-11C, an electronic display 522 can be provided that is similar in many respects to the electronic displays 222, 322, 422 illustrated in FIGS. 5-10 and described above. The electronic display 522 can comprise an electrophoretic display that can be configured similar to the electronic display 22 described above and illustrated in FIG. 2. As illustrated in FIG. 11A, the electronic display 522 can be operated such that all the black particles (e.g., 40) are activated to facilitate displaying of a black screen. As will be subsequently discussed, a patterned portion 568 of the electronic display 522, as illustrated in FIG. 11B, can be exposed to a freezing method to effectively bond the black particles (e.g., 40 of FIG. 2) of the patterned portion 568 adjacent to an upper electrode (e.g., 42 of FIG. 2) of the electronic display 522. When the electronic display 522 is in the deactivated state, as illustrated in FIG. 11B, the entire screen of the electronic display 522 remains one color (e.g., black). When the electronic display 522, is alternated to the activated state, as illustrated in FIG. 11C, the black particles that were not exposed to freezing method move away from the portion of the electronic display 522 (e.g., the portion surrounding the patterned portion 568). Thus the portion not exposed to the freezing method changes color to reveal the patterned portion 568 as an image on the electronic display 522.

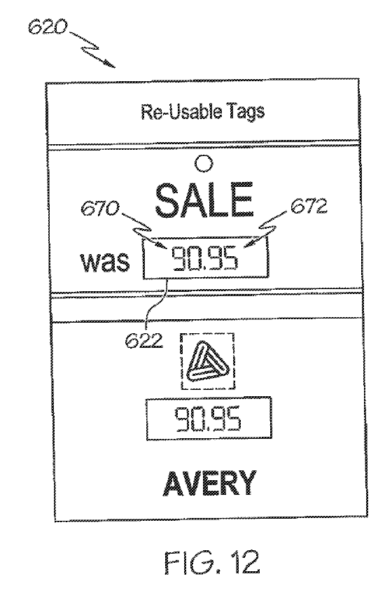

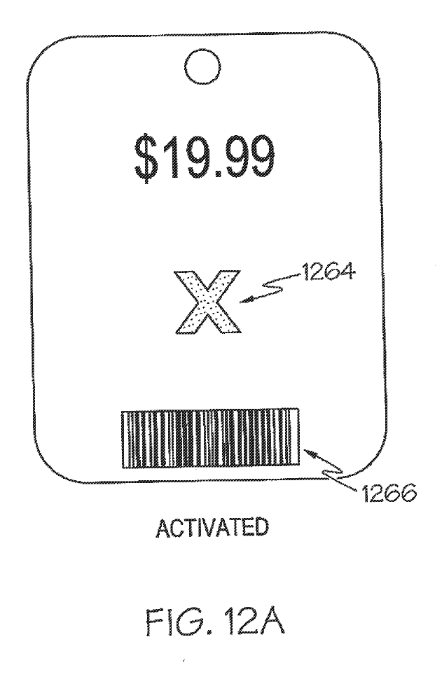

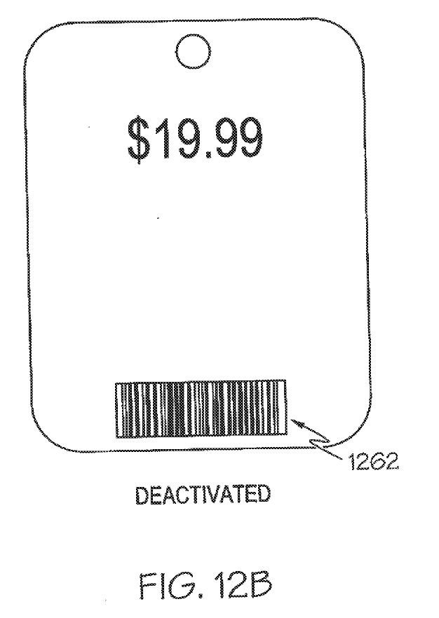

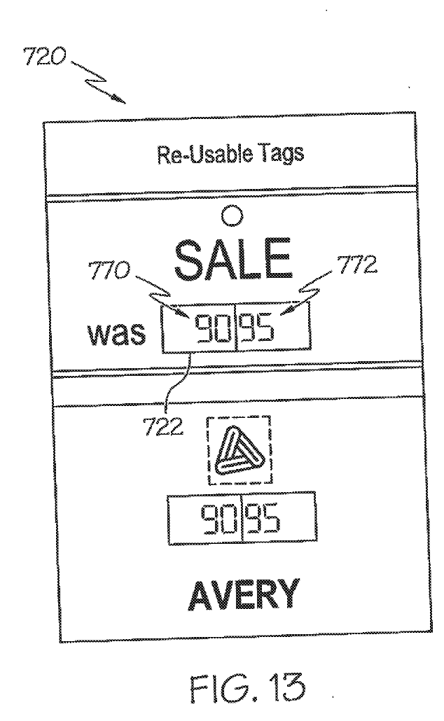

Referring now to FIG. 12, a retail tag 620 can be provided that can include an electronic display 622. The display 622 can be any of the displays discussed above such as a multiplexed display, a display with at least one digit of the pricing information “frozen” and not changeable by the RFID activator, or a display that can be activated or deactivated. In one embodiment, the retail tag can include a customizable portion 670 and a non-customizable portion 672. As illustrated in FIG. 12, the customizable portion 670 can display a dollar amount (e.g., the portion that precedes a decimal point), and the non-customizable portion 672 can display a cents amount (e.g., the portion that follows the decimal point). The customizable portion 670 can be programmable such that any of a variety of one or more digit numbers (e.g., 0-9999) can be displayed by the customizable portion 670. The non-customizable portion 672 can be non-programmable such that the non-customizable portion 672 is capable of only displaying one number (e.g., ‘95’). Although in an alternative embodiment, the customizable portion 670 can be configured as a customizable display (e.g., similar to the electronic displays 22, 122 described above and illustrated in FIGS. 1 and 3). In such an embodiment, the non-customizable portion 672 can be configured as a “freezable” display (e.g., similar to the electronic displays 222, 322, 422, 522 described above and illustrated in FIGS. 5-10).

FIGS. 12A and 12B provide retail tags in combination with other machine readable indicia such as bar codes 1262 and 1266, in which one tag has been activated 1264 as shown by a display and the other tag remains inactive or has been deactivated. In this manner, the consumer may be able to determine which articles are currently being offered for a discount or other promotion.

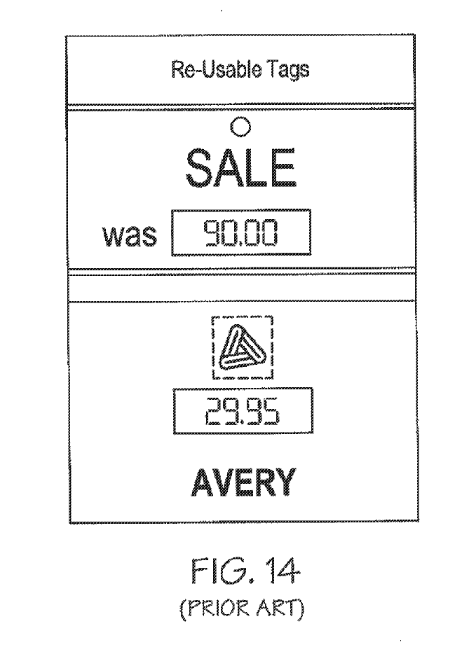

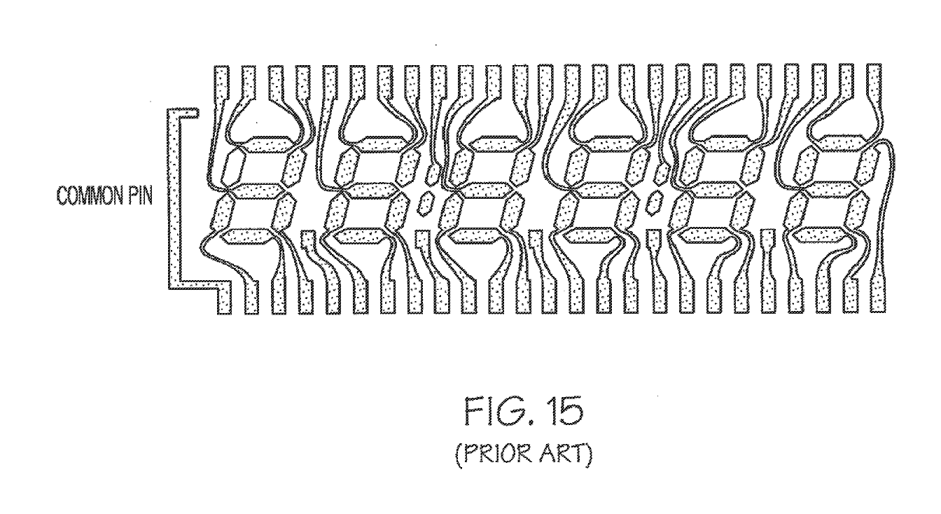

Prior art is illustrated by FIGS. 14 and 15. A retail tag as illustrated in FIG. 14, prior art includes a retail tag that has a fully wirelessly updateable four-digit electronic display, without showing the initial price. As illustrated in FIG. 15, each updateable digit of the display module can include 7 electrical connections. Since only two digits of the retail tags 620, 720 are customizable displays, the electrical connections for powering these LCD displays can be reduced, which can provide a more cost effective, efficient, and more compact solution over conventional retail tags and can also improve the ease of assembly of the retail tags 620, 720.

In an alternative embodiment, as illustrated in FIG. 13, a retail tag 720 includes an electronic display 722 with a customizable portion 770 and a non-customizable portion 772. The customizable portion 770 can comprise an electronic display that is similar to the customizable portion 670 shown in FIG. 12. The non-customizable portion 772 may not comprise an electronic display but might instead comprise a preprinted surface of the retail tag 720. It will be appreciated that an RFID activator can facilitate operation and updating of the customizable portion 670 of FIG. 12 and the customizable portion 770 of FIG. 13 in a similar manner as described above with respect to the electronic displays.

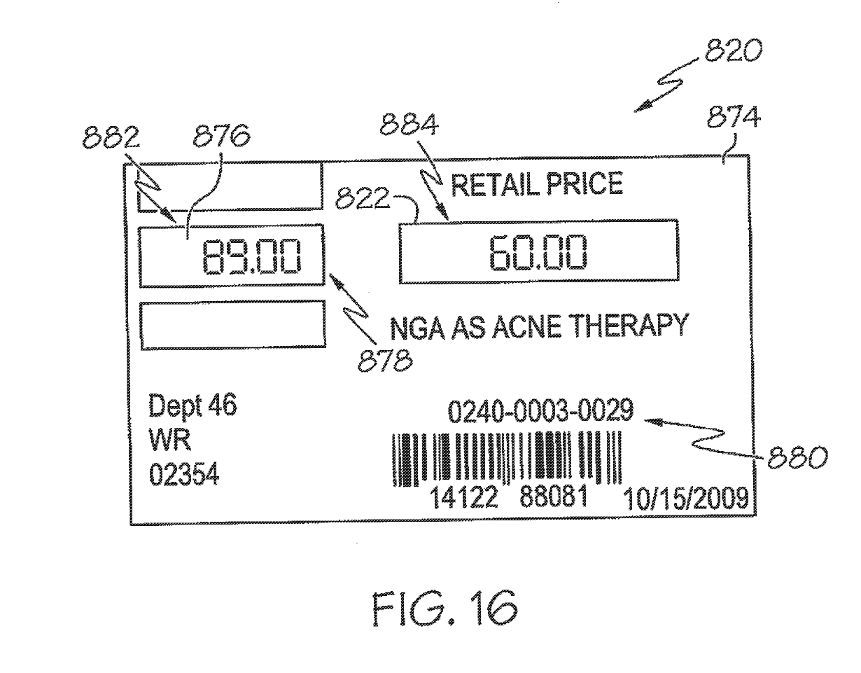

It will be appreciated that a body (e.g., 21, 121) of a retail tag (e.g., 20, 120) can be formed from any of a variety of suitable materials. In one embodiment, a retail tag can comprise a laminated retail tag such that a body of the retail tag is formed from a pair of laminations. The laminated retail tag can include an electronic display. The body of the retail tag can define an opening to facilitate effective viewing of the electronic display. For example, as illustrated in FIG. 16, a laminated retail tag 820 can include a front lamination 874 and a rear lamination 876. Prior to affixing the front and rear laminations 874, 876 together, a suggested price indicia 878 (e.g., “$89.00”) can be printed on the rear lamination 876 and other product information 880 can be printed on the front lamination 874. The front lamination 874 can define a first viewing window 882 and a second viewing window 884. The rear lamination 876 can define a rear viewing window that coincides with the second viewing window 884 of the front lamination 874. When the front and rear laminations 874, 876 are affixed together, as illustrated in FIG. 16, the suggested price indicia 878 can be viewed through the first viewing window 882. The second viewing window 884 of the front lamination 874 can be substantially aligned with the rear viewing widow of the rear lamination 876 to define an aperture through which an electronic display 822 can be viewed.

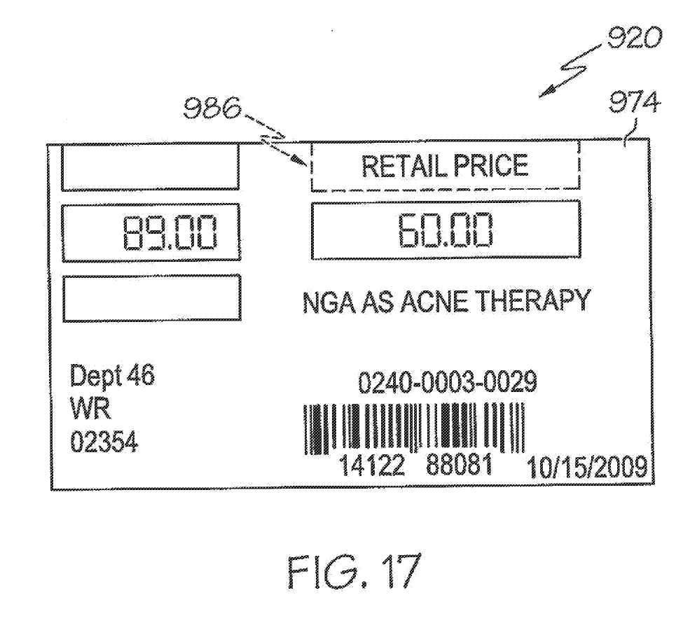

In another example, as illustrated in FIG. 17, a laminated retail tag 920 can be provided that is similar to the laminated retail tag 820 shown in FIG. 16. However, a front pocket 986 can be attached to a front lamination 974 of the laminated retail tag 920. Supplemental printed product information can be inserted into the front pocket 986 for display with the laminated retail tag 920. The supplemental information provided in the front pocket 986 can be selectively changed, which can allow the laminated retail tag 986 to be reused. It will be appreciated that in other embodiments, more than one pocket can be attached to a retail tag.

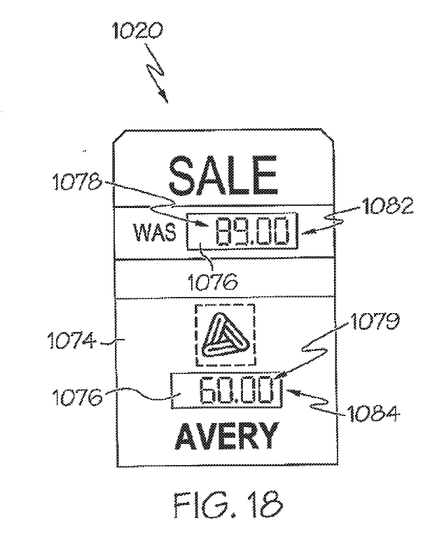

In another embodiment, a body of a laminated retail tag can be formed from two laminations that are configured to facilitate effective viewing of product information without use of an electronic display. For example, as illustrated in FIG. 18, a laminated retail tag 1020 can include a front lamination 1074 and a rear lamination 1076. Prior to affixing the front and rear laminations 1074, 1076 together, an original price indicia 1078 and a current price indicia 1079 can be printed on the rear lamination 1076, and other product information 1080 can be printed on the front lamination 1074. The front lamination 1074 can define a first viewing window 1082 and a second viewing window 1084. When the front and rear laminations 1074, 1076 are affixed together, as illustrated in FIG. 18, the original price indicia 1078 and the current price indicia 1079 can be viewed through the respective first and second viewing windows 1082, 1084.

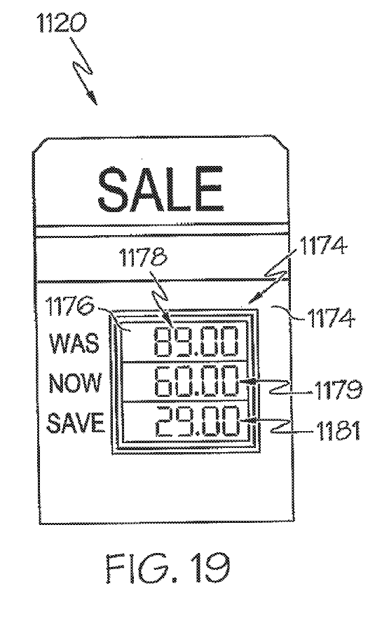

In another example, as illustrated in FIG. 19, a laminated retail tag 1120 can include a front lamination 1174 and a rear lamination 1176. Prior to affixing the front and rear laminations 1174, 1176 together, an original price indicia 1178, a current price indicia 1179, and a savings amount 1181 can be printed on the rear lamination 1176, and other product information 1180 can be printed on the front lamination 1174. The front lamination 1174 can define a viewing window 1182. When the front and rear laminations 1174, 1176 are affixed together, as illustrated in FIG. 18, the original price indicia 1178, the current price indicia 1179, and the savings amount 1181 can be viewed through the first viewing window 1182.

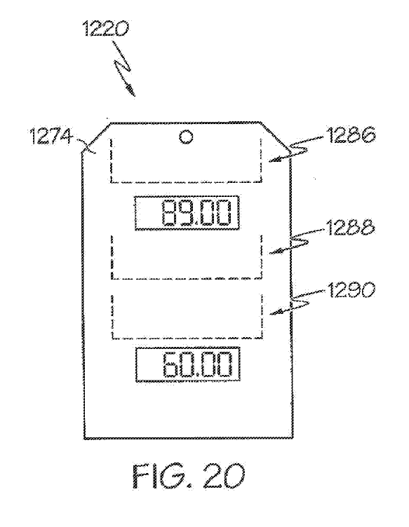

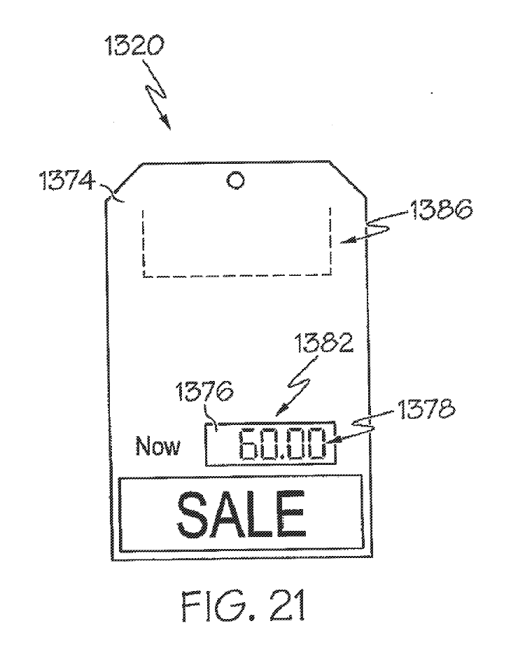

In yet another example, as illustrated in FIG. 20, a laminated retail tag 1220 can be provided that is similar to the laminated retail tag 1020 shown in FIG. 18. However, three front pockets 1286, 1288, 1290 can be attached to a front lamination 1274 of the laminated retail tag 1220. Supplemental printed product information can be inserted into the front pockets 1286, 1288, 1290 for display with the laminated retail tag 1220. In yet another example, as illustrated in FIG. 21, a laminated retail tag 1320 can include a front lamination 1374 and a rear lamination 1376. Prior to affixing the front and rear laminations 1374, 1376 together, a price indicia 1378 can be printed on the rear lamination 1376. The front lamination 1374 can define a viewing window 1382. When the front and rear laminations 1374, 1376 are affixed together, as illustrated in FIG. 21, the price indicia 1378 can be viewed through the viewing window 1382. A front pocket 1386 can be attached to a front lamination 1374 of the laminated retail tag 1320. Supplemental printed product information can be inserted into the front pocket 1386 for display with the laminated retail tag 1320.

The front and rear laminations of a laminated retail tag can be formed from plastic, vinyl, cardboard or any of a variety of other suitable laminate-type materials. In one example, a front and rear laminate can comprise 0.03 inch-thick vinyl film. It will be appreciated from FIG. 22B, that a retail tag can additionally or alternatively have product information printed upon a back of the retail tag. FIG. 22A illustrates a possible front view of the retail tag in FIG. 22B. It will also be appreciated that the specific shapes, styles, color, and proportions of the various components of a retail tag can differ from those depicted with respect to the retail tag and features depicted in FIGS. 1-22.

The retail tag described above may further include attaching means for securely attaching the tag to a retail product. For example, a small opening can be made in the retail tag and a string, strap, or a button hook can be employed to attach the tag to a retail product. The attaching mean may also include an adhesive on the back of the tag. The adhesive can be a pressure sensitive adhesive or an energy activatable adhesive such as heat activatable, UV activatable adhesive, etc. When a pressure sensitive is used, a protection sheet can be applied over the pressure sensitive layer to prevent pre-mature attachment of the electronic label to other contact surfaces. The protection sheet is removed before the electronic label is applied to the product.

The retail tag described above can also be recycled or reused for multiple turns through a retail environment. For example, the tags are first removed by the retailer, returned to a central point, and attached to new products. Prior to attachment, inspection can be conducted and malfunctioning parts such as batteries can be replaced, to ensure proper function of recycled tags. The tags can then be tested prior to being released back into the retail chain.

The retail labels described above can be installed on a shelf edge or a display rack. Product information (e.g., the product's price, its UPC barcode, or a product's applicable discounts) can be displayed on the electronic display. When the product information requires updating, the electronic display can be electronically updated to display the updated product information.

The foregoing description of embodiments and examples has been presented for purposes of illustration and description. It is not intended to be exhaustive or limiting to the forms described. Numerous modifications are possible in light of the above teachings. Some of those modifications have been discussed, and others will be understood by those skilled in the art. The embodiments were chosen and described in order to best illustrate principles of various embodiments as are suited to particular uses contemplated. The scope is, of course, not limited to the examples set forth herein, but can be employed in any number of applications and equivalent devices by those of ordinary skill in the art.

What is claimed is:

1. A retail item display device, comprising: an RFID device, a display driving mechanism, a power source, and a display module;
the RFID device includes at least a RFID antenna and an RFID processor;
the RFID device interacts with an external RFID activator to update information related to a retail product; and
wherein the RFID device communicates with the display driving mechanism to process and update the information and transfers the updated information to the electronic display.

2. A retail item display device as recited in claim 1, wherein the display driving mechanism includes at least one microcontroller and one display driver or similar devices and the microcontroller and the display driver can be either as separate components or integrated into a single component.

3. A retail item display device as recited in claim 2, wherein the display driving mechanism may further include a storage element to temporarily or permanently store the information related to the retail product.

4. A retail item display device as recited in claim 1, wherein the display driving mechanism communicates with the RFID device, processing the information and transferring the updated pricing information to the electronic display.

5. A retail item display device as recited in claim 1, wherein an analog to digital signal converting element may be included to convert RF signals from the RFID device to digital signal for processing by the display driving mechanism.

6. A retail item display device as recited in claim 2, wherein the display driving mechanism may further include a charge pump to amplify signal strength to a level necessary to activate the electronic display.

7. A retail item display device as recited in claim 1, wherein the RFID processor and the microcontroller can be integrated into a single component which communicates with a stand alone display driver to provide updated information related to a retail product on the electronic display.

8. A retail item display device as recited in claim 1, wherein the retail tag includes a first power source that can power components of the retail tag to facilitate communication with an external RFID activator to update product information.

9. A retail item display device as recited in claim 8, wherein the first power source includes a battery or an RF energy harvesting element.

10. A retail item display device as recited in claim 1, wherein the electronic display includes a display medium sandwiched between two electrodes.

11. A retail item display device as recited in claim 10, wherein the two electrodes include an upper and lower electrode where upper electrode is transparent so that the information can be observed through the transparent electrode and the bottom electrode can be either transparent or opaque, and contains TFT or pixel electrode to enable a high resolution display.

12. A retail item display device as recited in claim 10, wherein the display medium is selected from a group including electrochromic medium, liquid crystal medium, electrophoretic medium, electromagnetic medium and combinations thereof.

13. A retail item display device as recited in claim 8, wherein the retail tag includes a second power source.

14. A retail item display device as recited in claim 13, wherein the first and second power sources can be a battery or super capacitor, or a combination of a battery and a super capacitor.

15. A retail item display device as recited in claim 13, wherein the first power source is a rechargeable battery and the second power source is a super capacitor.

16. A retail item display device as recited in claim 15, wherein the super capacitor charges the rechargeable battery.

17. A retail item display device as recited in claim 13, wherein at least one of the first and second power sources is connected to both the RFID device and the display driving mechanism to provide power.

18. A retail item display device as recited in claim 13, wherein the second power source is connected directly to the display driving mechanism to ensure that price information remains visible in case that the first power source stops functioning.

19. A retail item display device, comprising;
an RFID device, a display driving mechanism, at least one power source, and an electronic display;
the electronic display including at least one customizable portion and at least one non-customizable portion, with the customizable portion configured to display an image that can be updated according to instructions from an external RFID activator and the RFID device; and
the non-customizable portion is configured to selectively display an image, such as a pre-printed image.

20. A method of manufacturing a retail tag comprising the steps of;
patterning electrodes and/or other conductive structures on a first plastic substrate;
transferring the electrodes or conductive structures to a second substrate; and
attaching the electrodes or conductive structures to other electronic elements on the second substrate.

21. A method of using a retail tag, comprising the steps of;
providing a retail item;
supplying an item display device;
connecting the item display device to the retail item;
determining a price for the retail item;
transmitting the price to the item display device; and
displaying the price along with other indicia related to the retail item.

22. A laminated retail tag, comprising;
a first substrate having a viewing window and having a first face and a second face, with the first face having printing around the window consisting of an opening or a clear material.
a second substrate having a first face and a second face with printing on the second face and matching the printing on the first face of the first substrate; and
a RFID device, at least one power source, a display driving mechanism, and an electronic display positioned between the first and second substrate such that the electronic display is visible through the window.

23. A retail item display device comprising: an RFID device, a display driving mechanism, at least one power source, and an electronic display;
the RFID device interacts with an external RFID activator to update information related to an item;
the RFID device communicates with the display driving mechanism to process and update the information and transfer the updated information to the electronic display;
the electronic display is arranged to reduce the number of electrical connections between the display module and the display driving mechanism.

24. The retail item display of claim 23, wherein the RFID device includes an RFID antenna and an RFID device.

25. The retail item display device of claim 23, wherein the electronic display comprises a multiplexed display.

26. The retail item display device of claim 23, wherein at least one of the characters is not updated by the RFID activator.

27. The retail item display device of claim 23, wherein two characters are not updateable by the RFID activator.

28. The retail item display device of claim 23, wherein the electronic display displays an updated pricing information in “OFF %!”.

29. The electronic display of claim 26, wherein the “OFF %!” can be activated or deactivated by the RFID activator.
